(19) United States
(12) Patent Application Publication
(10) Pub. No.: US 2026/0239872 A1
(43) Pub. Date: Aug. 13, 2026

(54) METHOD OF TREATING SEMICONDUCTOR NANOPARTICLE, SEMICONDUCTOR NANOPARTICLE, ELECTROLUMINESCENT DEVICE INCLUDING THE SAME

(71) Applicants: SAMSUNG ELECTRONICS CO., LTD., Suwon-si (KR); Samsung Display Co., Ltd., Yongin-si (KR)

(72) Inventors: DAEUN YOON, Suwon-si (KR); HYUN DONG HA, Suwon-si (KR); Hogeun Chang, Suwon-si (KR); Jae Yong LEE, Suwon-si (KR); Ji Hyun MIN, Suwon-si (KR); Kwang Hee KIM, Suwon-si (KR)

(21) Appl. No.: 19/532,301

(22) Filed: Feb. 6, 2026

(30) Foreign Application Priority Data
Feb. 7, 2025 (KR) 10-2025-0016190

(51) Int. Cl. H10K 85/30; B82Y 20/00; B82Y 40/00; C09D 11/037; C09D 11/50; C09K 11/02; C09K 11/88; H10K 50/115; H10K 59/35

(52) U.S. Cl. CPC H10K 85/381; C09D 11/037; C09D 11/50; C09K 11/025; C09K 11/883; B82Y 20/00; B82Y 40/00; H10K 50/115; H10K 59/35

(57) ABSTRACT

A method of treating a semiconductor nanoparticle, a semiconductor nanoparticle, and an electroluminescent device and a display device including the semiconductor nanoparticle. The method includes: adding a metal halide to a first dispersion including a liquid medium and a semiconductor nanoparticle dispersed in the liquid medium, precipitating the semiconductor nanoparticle to provide a precipitated semiconductor nanoparticle; adding a ligand compound to the first dispersion and mixing the ligand compound with the first dispersion including the precipitated semiconductor nanoparticle, obtaining a second dispersion in which a semiconductor nanoparticle surface-treated with the ligand compound is dispersed in the liquid medium to provide a surface-treated semiconductor nanoparticle; and recovering the surface-treated semiconductor nanoparticle from the second dispersion.

### CROSS-REFERENCE TO RELATED APPLICATION

This application is based on and claims priority to Korean Patent Application No. 10-2025-0016190, filed on Feb. 7, 2025, in the Korean Intellectual Property Office, and all the benefits accruing therefrom under 35 U.S.C. § 119, the content of which in its entirety is incorporated herein by reference.

### BACKGROUND

### 1. Field

The present disclosure relates to a method for treating a semiconductor nanoparticle, a (surface-treated) semiconductor nanoparticle or an ink composition including the semiconductor nanoparticle, and an electroluminescent device and a display device including the semiconductor nanoparticle.

### 2. Description of the Related Art

A semiconductor nanoparticle may exhibit different aspects, characteristics, or properties compared to a corresponding bulk material having substantially the same composition. For example, the semiconductor nanoparticle may have different physical properties based on the nanostructure (e.g., bandgap energy, a luminescent property, or the like). The semiconductor nanoparticle may be configured to emit light upon excitation by incident light or an applied voltage. The luminescent nanostructure may find applicability in a variety of devices (e.g., a display panel or an electronic device including the display panel). From an environmental point of view, developing a luminescent nanoparticle that does not contain a harmful heavy metal such as cadmium, and still achieves comparable or an improvement in one or more luminescent or optical properties is of interest and desirable.

### SUMMARY

The embodiments relate to a method for surface-treating a semiconductor nanoparticle.

The embodiments relate to a semiconductor nanoparticle capable of realizing improved properties (e.g., an electroluminescent property and a lifetime property of a device).

The embodiments relate to a light emitting device (e.g., an electroluminescent device) that emits light by itself upon application of a voltage to the semiconductor nanoparticle (e.g., a quantum dot).

The embodiments relate to a display device (e.g., a QD-LED display) including a nanocrystal particle (e.g., a quantum dot) as a light emitting material in a red/green/blue pixel.

In an embodiment, a method for treating a semiconductor nanoparticle comprises: adding a metal halide to a first dispersion including a liquid medium and a semiconductor nanoparticle (e.g., dispersed in the liquid medium) to precipitate the semiconductor nanoparticle to provide a precipitated semiconductor nanoparticle;
adding a ligand compound to the first dispersion and mixing the ligand compound with the first dispersion including the precipitated semiconductor nanoparticle to obtain a second dispersion in which a semiconductor nanoparticle surface treated with the ligand compound is dispersed in the liquid medium to provide a surface-treated semiconductor nanoparticle; and
recovering the surface-treated semiconductor nanoparticle from the second dispersion.

The metal halide may include zinc, aluminum, indium, gallium, or a combination thereof.

The metal halide may include ZnCl₂, AlCl₃, InCl₃, GaCl₃, ZnI₂, or a combination thereof.

The liquid medium may include one or more (e.g., two or more) organic solvents.

The organic solvent may have a boiling point of greater than or equal to about 130° C., greater than or equal to about 150° C., or greater than or equal to about 180° C. and less than or equal to about 400° C. at atmospheric pressure. The boiling point may be greater than or equal to about 200° C. and less than or equal to about 380° C.

The liquid medium may include a substituted or unsubstituted C6 to C40 aromatic hydrocarbon solvent; a substituted or unsubstituted C6 to C15 aliphatic hydrocarbon solvent; a substituted or unsubstituted C6 to C40 amine solvent; or a combination thereof.

The liquid medium may include cyclohexylbenzene, trioctylamine, or a combination thereof.

The ligand compound may include a carboxyl group, an amine group, or a combination thereof.

The surface-treated semiconductor nanoparticle may include a first organic ligand. The first organic ligand may be derived from the ligand compound. The ligand compound comprises a compound represented by Chemical Formula 2:

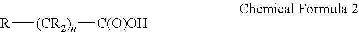

wherein, in Chemical Formula 2, each R may be the same or different and each independently hydrogen or a C1 to C6 alkyl group, and n may be an integer of 1 to 10.

The surface-treated semiconductor nanoparticle (e.g., in the first dispersion) may include a second organic ligand different from the first organic ligand. The first organic ligand may include a carboxylate group, an amine moiety, or a combination thereof. The second organic ligand may include a carboxylate group, an amine group, or a combination thereof.

The first organic ligand may have a number of carbon atoms that is greater than or equal to about 2, or greater than or equal to about 5 and less than or equal to about 16, less than or equal to about 14, or less than or equal to about 10. The second organic ligand may have a number of carbon atoms that is greater than or equal to about 14, or greater than or equal to about 17 and less than or equal to about 40, or less than or equal to about 24. The second organic ligand may have a molecular weight greater than that of the first organic ligand.

The first organic ligand may include a hexanoate group, a methylbutanoate group, a butyloctanoate group, or a combination thereof. The first organic ligand may include a hexanoate moiety substituted with a C1-C4 alkyl group, a butanoate moiety substituted with a C1-C4 alkyl group, a pentanoate moiety substituted with a C1-C4 alkyl group, an octanoate moiety substituted with a C1-C4 alkyl group, or a combination thereof.

The second organic ligand may include a linear or branched aliphatic hydrocarbon group (e.g., an alkyl group, an alkenyl group, or an alkynyl group) of C13-C25, C14-C23, C15-C22, C16-C21, C17-C20, or C18-C19. The second organic ligand may include an aliphatic hydrocarbon group of greater than or equal to about C17.

The second organic ligand may include, for example, one or more, or two or more, carbon-carbon double bond in the aliphatic hydrocarbon group chain. The first organic ligand may include a branched alkyl group, and the second organic ligand may include a linear alkenyl group. The first organic ligand may be bonded to or disposed on a surface of the semiconductor nanocrystal. The second organic ligand may be bonded to or disposed on the surface of the semiconductor nanocrystal.

A total of the number of carbon atoms of the first organic ligand and the second organic ligand may be greater than or equal to about 20, greater than or equal to about 22, greater than or equal to about 24, greater than or equal to about 28, or greater than or equal to about 29. The total of the number of carbon atoms may be less than or equal to about 34, less than or equal to about 32, less than or equal to about 30, less than or equal to about 28, or less than or equal to about 27.

The first organic ligand may have a molecular weight that is greater than or equal to about 90 grams per mole (g/mol), or greater than or equal to about 100 g/mol and less than or equal to about 260 g/mol, less than or equal to about 230 g/mol, less than or equal to about 210 g/mol, less than or equal to about 205 g/mol, less than or equal to about 200 g/mol, or less than or equal to about 170 g/mol.

The second organic ligand may have a molecular weight of greater than about 200 g/mol, greater than or equal to about 225 g/mol, greater than or equal to about 250 g/mol, or greater than or equal to about 280 g/mol, and less than or equal to about 500 g/mol, or less than or equal to about 250 g/mol.

The first organic ligand may include a substituted or unsubstituted C6 to C12 aromatic hydrocarbon group; a substituted or unsubstituted linear or branched aliphatic hydrocarbon group of C3 to C12, C5 to C9, C4 to C8, or C6 to C7 (e.g., an alkyl group, an alkenyl group, or an alkynyl group); or a combination thereof.

The mixing may be performed at a temperature of greater than or equal to about 120° C., or greater than or equal to about 160° C. The mixing may be performed at a temperature of less than or equal to about 250° C., or less than or equal to about 240° C.

The metal halide may be added to the first dispersion in a solution state of a solvent miscible with the liquid medium. The solvent may include a C3-C10 ketone solvent such as acetone, a C1-C10 alcohol solvent such as ethanol, a C1-C40 or C3-C30 alkylphosphine solvent such as trioctylphosphine, or a combination thereof.

The metal halide may be added in an amount with a concentration in the liquid medium that is greater than or equal to about 0.00001 molar (M), greater than or equal to about 0.00005 M, greater than or equal to about 0.0001 M, greater than or equal to about 0.0005 M, greater than or equal to about 0.001 M, greater than or equal to about 0.005 M, or greater than or equal to about 0.01 M and less than or equal to about 100 M. An amount of the ligand compound may be, based on the metal halide, less than or equal to about 5000 mole %, or in a range of greater than or equal to about 0.01 mole % and less than or equal to about 1000 mole %.

Addition of the metal halide may precipitate greater than or equal to about 80%, or greater than or equal to about 90%, of the semiconductor nanoparticles in the first dispersion. Addition of the metal halide may precipitate greater than or equal to about 95%, or greater than or equal to about 99%, of the semiconductor nanoparticles in the first dispersion. The recovering may include adding a precipitation solvent to the second dispersion. The precipitation solvent may include acetone, ethanol, butanol, isopropanol, ethanediol, water, tetrahydrofuran (THF), dimethyl sulfoxide (DMSO), diethyl ether, formaldehyde, acetaldehyde, ethylene glycol, or a solvent having a solubility parameter similar to that of the listed solvents.

An embodiment relates to a semiconductor nanoparticle, including: a first semiconductor nanocrystal; and a semiconductor nanocrystal shell disposed on the first semiconductor nanocrystal. The semiconductor nanoparticle further includes a plurality of organic ligands. The plurality of organic ligands includes a first organic ligand and optionally a second organic ligand different from the first organic ligand. The first organic ligand includes a branched alkyl group of C3 to C12, and the second organic ligand includes an alkenyl group of C13 to C30. The semiconductor nanoparticle exhibits, in gas chromatography analysis, a first peak assigned to the first organic ligand and optionally a second peak assigned to the second organic ligand. A fraction of the second organic ligand defined by the following equation is greater than or equal to about 0% and less than or equal to about 60%:

$$Second organic ligand fraction = [ \text{} second peak area correction value / ( first peak area correction value + second peak area correction value ) ] \times 100 ( \% )$$

wherein the second peak area correction value is a value obtained by dividing an area of the second peak by a molecular weight of the second organic ligand, and the first peak area correction value is a value obtained by dividing an area of the first peak by a molecular weight of the first organic ligand.

An embodiment relates to an ink composition including a semiconductor nanoparticle (for example, treated by the treatment method described above) and a liquid vehicle. The ink composition includes a liquid vehicle; and a semiconductor nanoparticle, where the liquid vehicle includes an organic solvent having a boiling point of greater than or equal to about 150° C. and less than or equal to about 380° C. The semiconductor nanoparticle further includes a plurality of organic ligands. The plurality of organic ligands includes a first organic ligand; and a second organic ligand different from the first organic ligand. The first organic ligand includes a branched alkyl group of C3 to C12, and the second organic ligand includes an alkenyl group of C13 to C30. The semiconductor nanoparticle exhibits a first peak assigned to the first organic ligand and a second peak assigned to the second organic ligand, in gas chromatography analysis. A fraction of the second organic ligand as defined by the following equation is less than or equal to about 60%:

$$second organic ligand fraction = [ \text{} second peak area correction value / ( first peak area correction value + second peak area correction value ) ] \times 100 ( \% )$$

where the second peak area correction value is a value obtained by dividing an area of the second peak by a molecular weight of the second organic ligand, and the first peak area correction value is a value obtained by dividing an area of the first peak by a molecular weight of the first organic ligand.

The liquid vehicle may include an organic solvent having a boiling point of greater than or equal to about 130° C. or greater than or equal to about 150° C. and less than or equal to about 380° C., and the semiconductor nanoparticle may include a first organic ligand having a number of carbon atoms of greater than or equal to about 2 and less than or equal to about 16.

In the ink composition, the semiconductor nanoparticle may have a dynamic light scattering (DLS) particle diameter of greater than or equal to about 1 nanometers (nm) and less than about 400 nm, or greater than or equal to about 5 nm and less than or equal to about 100 nm.

The liquid vehicle may include a substituted or unsubstituted C6 to C40 aromatic hydrocarbon solvent; a substituted or unsubstituted C6 to C15 aliphatic hydrocarbon solvent; a substituted or unsubstituted C6 to C40 amine solvent; or a combination thereof. The liquid vehicle may include cyclohexylbenzene, trioctylamine, or a combination thereof.

In an embodiment, the semiconductor nanoparticle may include a first semiconductor nanocrystal; and a semiconductor nanocrystal shell disposed on the first semiconductor nanocrystal.

The semiconductor nanoparticle may include a plurality of organic ligands (or a ligand system including the same), and the plurality of organic ligands may include a first organic ligand; and a second organic ligand different from the first organic ligand. The semiconductor nanoparticle may exhibit, in gas chromatography (GC) analysis, a first peak assigned to the first organic ligand and a second peak assigned to the second organic ligand.

In the surface-treated semiconductor nanoparticle, a second organic ligand fraction calculated by the following equation may be less than or equal to about 80%, less than or equal to about 79%, or less than or equal to about 75%:

$$second organic ligand fraction = [ \text{} corrected value of a second peak area / corrected value of the second peak area + corrected value of a first peak area ) ] \times 100 ( \% ) .$$

The corrected value of the second peak area is a value obtained by dividing an area of the second peak by a molecular weight of the second organic ligand, and the corrected value of the first peak area is a value obtained by dividing an area of the first peak by a molecular weight of the first organic ligand.

The semiconductor nanoparticle may include zinc, sulfur, and selenium and may not include cadmium. The first organic ligand and the second organic ligand may each have a carboxylate moiety. The first organic ligand may include a branched alkyl group of C3 to C12 or C4 to C8. The second organic ligand may include an alkenyl group of C13 to C30 or C16 to C24.

Details of the first organic ligand and the second organic ligand are as described herein.

In thermogravimetric analysis, the semiconductor nanoparticle may have a weight loss (e.g., an organic content) decreased in a range of greater than or equal to about 200° C. and less than or equal to about 550° C. of less than or equal to about 13 weight percent (wt) %, less than or equal to about 11.5 wt %, less than or equal to about 11 wt %, less than or equal to about 8 wt %, less than or equal to about 7.5 wt %, less than or equal to about 7.3 wt %, or less than or equal to about 6 wt %, based on a total weight of the semiconductor nanoparticle. In thermogravimetric analysis, the semiconductor nanoparticle may have a weight loss decreased in a range of greater than or equal to about 200° C. and less than or equal to about 550° C. of greater than or equal to about 1 weight percent (wt %), or greater than or equal to about 3 wt %, based on the total weight of the semiconductor nanoparticle.

In thermogravimetric analysis, the semiconductor nanoparticle may have a residue content at greater than or equal to about 550° C. of greater than or equal to about 82%, greater than or equal to about 87%, greater than or equal to about 88%, or greater than or equal to about 89%, and less than or equal to about 99%, less than or equal to about 93%, or less than or equal to about 91%, based on the total weight of the semiconductor nanoparticle.

A ratio of a retention time (minutes) of the first peak to a retention time (minutes) of the second peak may be greater than or equal to about 0.1, greater than or equal to about 0.5, or greater than or equal to about 0.7 and less than or equal to about 1, or less than or equal to about 0.9. The retention time of the second peak may be longer than the retention time of the first peak. A difference between the retention time of the second peak and the retention time of the first peak may be greater than or equal to about 2 minutes, or greater than or equal to about 5 minutes. The difference between the retention time of the second peak and the retention time of the first peak may be less than or equal to about 12 minutes, or less than or equal to about 10 minutes.

The semiconductor nanoparticle may further include a halogen (e.g., chlorine).

In the semiconductor nanoparticle, a mole ratio of halogen (e.g., chlorine) to zinc (e.g., Cl:Zn) may be greater than or equal to about 0.01:1, greater than or equal to about 0.05:1, greater than or equal to about 0.1:1, greater than or equal to about 0.15:1, or greater than or equal to about 0.2:1. In the semiconductor nanoparticle, the mole ratio of halogen (e.g., chlorine) to zinc (e.g., Cl:Zn) may be less than or equal to about 1:1, less than or equal to about 0.9:1, less than or equal to about 0.7:1, or less than or equal to about 0.5:1.

The semiconductor nanoparticle, the first semiconductor nanocrystal, or the semiconductor nanocrystal shell may include a II-VI group compound, a III-V group compound, a IV-VI group compound, a group IV element or compound, a II-III-VI group compound, a I-III-VI group compound, a I-II-IV-VI group compound, or a combination thereof.

The semiconductor nanoparticle or the first semiconductor nanocrystal may include an indium phosphide, an indium zinc phosphide, a zinc selenide, a zinc telluride, a zinc tellurium selenide, a silver indium gallium sulfide, a silver indium sulfide, or a combination thereof.

The semiconductor nanoparticle or the semiconductor nanocrystal shell may include a zinc selenide, a zinc selenide telluride, a zinc selenide sulfide, a zinc sulfide, or a combination thereof.

The semiconductor nanocrystal shell may include a first shell layer; and a second shell layer disposed on the first shell layer. The first shell layer may include a zinc selenide, a zinc selenide telluride, a zinc selenide sulfide, or a combination thereof. The second shell layer may include a zinc selenide sulfide, a zinc sulfide, or a combination thereof.

The semiconductor nanoparticle may not include lead. The semiconductor nanoparticle may not include copper.

The semiconductor nanoparticle may be configured to emit first light.

The first light may exhibit a red light spectrum, a green light spectrum, or a blue light spectrum. The first light may have a full width at half maximum of an emission peak of greater than or equal to about 1 nm and less than or equal to about 55 nm.

The first light may be blue light. A peak emission wavelength of the first light or the blue light may be greater than or equal to about 440 nm and less than or equal to about 480 nm.

The first light may be green light. A peak emission wavelength of the first light or the green light may be greater than or equal to about 500 nm and less than or equal to about 580 nm.

The first light may be red light. A peak emission wavelength of the first light or the red light may be greater than or equal to about 600 nm and less than or equal to about 680 nm.

The semiconductor nanoparticle may substantially not exhibit, in a gas chromatogram, a peak assigned to a thiol. In the gas chromatogram, an area ratio of a peak assigned to a thiol relative to the second peak may be less than or equal to about 10%, less than or equal to about 5%, less than or equal to about 2%, or less than or equal to about 1%.

The semiconductor nanoparticle may have a particle size or an average particle size (hereinafter, referred to as “particle size”) of greater than or equal to about 3 nm, greater than or equal to about 5 nm, greater than or equal to about 8 nm, greater than or equal to about 10 nm, or greater than or equal to about 12 nm and less than or equal to about 50 nm, or less than or equal to about 45 nm.

The semiconductor nanoparticle may exhibit, in dynamic light scattering (DLS) analysis, a DLS particle diameter of less than about 300 nm. The DLS particle diameter may be less than or equal to about 200 nm, less than or equal to about 100 nm, or less than or equal to about 50 nm. The DLS particle diameter may be greater than or equal to about 10 nm, or greater than or equal to about 15 nm.

In an embodiment, an electroluminescent device comprises a first electrode and a second electrode that are spaced apart from each other, and an emission layer disposed between the first electrode and the second electrode, and the emission layer comprises the semiconductor nanoparticle described above.

Details of the semiconductor nanoparticle are as described herein.

The emission layer may be configured to emit first light by application of a voltage.

Details of the first light are as described herein. In an embodiment, a peak emission wavelength of the first light or the semiconductor nanoparticle (electroluminescent or photoluminescent) may be greater than or equal to about 440 nm, or greater than or equal to about 460 nm and less than or equal to about 480 nm, or less than or equal to about 470 nm.

In an embodiment, a peak emission wavelength of the first light or the semiconductor nanoparticle may be greater than or equal to about 500 nm, or greater than or equal to about 510 nm and less than or equal to about 580 nm, or less than or equal to about 540 nm. In an embodiment, a peak emission wavelength of the first light or the semiconductor nanoparticle may be greater than or equal to about 600 nm, or greater than or equal to about 610 nm and less than or equal to about 680 nm, or less than or equal to about 635 nm.

The first electrode may be an anode, and the second electrode may be a cathode.

The electroluminescent device may further include a charge auxiliary layer between the emission layer and the first electrode, between the emission layer and the second electrode, or both.

The electroluminescent device may further include a hole auxiliary layer between the emission layer and the first electrode. The electroluminescent device may further include an electron auxiliary layer between the emission layer and the second electrode.

The charge auxiliary layer may include a hole auxiliary layer including an organic compound, an electron auxiliary layer including metal oxide fine particles, or a combination thereof.

The electroluminescent device may have a maximum luminance of greater than or equal to about 10,000 candela per square meters (cd/m²), greater than or equal to about 80,000 cd/m², greater than or equal to about 90,000 cd/m², or greater than or equal to about 100,000 cd/m².

The electroluminescent device may have a maximum external quantum efficiency of greater than or equal to about 3%, greater than or equal to about 5%, greater than or equal to about 9%, greater than or equal to about 10%, or greater than or equal to about 11%.

The electroluminescent device may have a T90 of greater than or equal to about 10 hours, or greater than or equal to about 30 hours (for example, when measured at an initial luminance of 146 nit).

An embodiment relates to an electronic device or a display device including the electroluminescent device.

The display device or the electronic device may include a virtual reality display device, an augmented reality display device, a portable terminal device, a monitor, a notebook computer, a television, an electronic signboard, a camera, or an automotive electronic component.

According to an embodiment, the semiconductor nanoparticle can realize improved optical properties and lifetime properties when applied to, for example, an electroluminescent device, and can exhibit dispersion characteristics suitable for being provided as an ink composition.

### BRIEF DESCRIPTION OF THE DRAWINGS

The above and other aspects, features, and advantages of certain exemplary embodiments will be more apparent from the following detailed description taken in conjunction with the accompanying drawings.

FIG. 1 is a schematic cross-sectional view of an embodiment of a quantum dot light emitting diode (“QD-LED”) device.

FIG. 2 is a schematic cross-sectional view of an embodiment of a QD-LED device.

FIG. 3 is a schematic cross-sectional view of an embodiment of a QD-LED device.

FIG. 4 is a schematic cross-sectional view of a QD-LED device according to an embodiment.

FIG. 5 is a schematic cross-sectional view of a light emitting device (RGB pixel) according to an embodiment.

FIG. 6 is a schematic front view of a display panel according to an embodiment.

FIG. 7 is a schematic cross-sectional view of the display panel of FIG. 6 taken along line IV-IV.

FIG. 8 is a view showing results of gas chromatography analysis of a semiconductor nanoparticle synthesized in Reference Example 1.

FIG. 9 is a view showing results of gas chromatography analysis of a semiconductor nanoparticle synthesized in Preparation Example 1.

FIG. 10 is a view showing results of gas chromatography analysis of a semiconductor nanoparticle synthesized in Preparation Example 2.

### DETAILED DESCRIPTION

Advantages and characteristics of this disclosure, and a method for achieving the same, will become evident referring to the following exemplary embodiments together with the drawings attached hereto. However, this invention may be embodied in many different forms, the embodiments should not be construed as being limited to the embodiments set forth herein. Rather, these embodiments are provided so that this disclosure will be thorough and complete, and will fully convey the scope of the invention to those skilled in the art. Like reference numerals refer to like elements throughout.

In order to clearly explain the present disclosure, parts irrelevant to the description are omitted, and the same reference numerals are assigned to the same or similar elements throughout the specification. In the drawings, the thickness of layers, films, panels, regions, etc., are exaggerated for clarity. And in the drawings, for convenience of description, the thickness of some layers and regions are exaggerated. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above”.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as being limited to “a” or “an.” “Or” means “and/or.”

As used herein, the term “and/or” comprises any and all combinations of one or more of the associated listed items. It will be further understood that the terms “comprises” and/or “comprising,” or “comprises” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, the term “cross-sectional” means a case in which a cross-section of a given object is cut, for example, in a substantially vertical direction and is viewed laterally. Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

As used herein, values of a work function, a conduction band, or a lowest unoccupied molecular orbital (LUMO) (or valence band, or highest occupied molecular orbital (HOMO)) energy level is expressed as an absolute value from a vacuum level. In addition, when the work function or the energy level is referred to be “deep,” “high” or “large,” the work function or the energy level has a large absolute value based on “0 electron volt (eV)” of the vacuum level, while when the work function or the energy level is referred to be “shallow,” “low,” or “small,” the work function or energy level has a small absolute value based on “0 electron volt (eV)” of the vacuum level. In an aspect, work function herein refers to a minimum energy required to remove an electron from e.g., a solid metal (e.g., a metal surface) to vacuum (e.g., immediately outside the solid surface).

As used herein, the average (value) may be mean or median. In an embodiment, the average (value) may be a mean value.

As used herein, the term “peak emission wavelength” is the wavelength at which a given emission spectrum of the light reaches its maximum.

As used herein, the term “first absorption peak” refers to a main excitonic peak appearing first from the longest wavelength region of a ultraviolet-visual (UV-Vis) absorption spectrum (i.e., appearing in the lowest energy region in the UV-Vis absorption spectrum), and the term “first absorption peak wavelength” or “wavelength of the first absorption peak” refers to the wavelength at which the first absorption peak reaches a maximum intensity.

As used herein, the term “Group” may refer to a group of Periodic Table.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group IIIA metal may be Al, In, Ga, and Tl, and examples of Group IIIB may be scandium, yttrium, or the like, but are not limited thereto.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto.

As used herein, “Group V” comprises Group VA and comprises nitrogen, phosphorus, arsenic, antimony, and bismuth, but is not limited thereto.

As used herein, “Group VI” comprises Group VIA and comprises sulfur, selenium, and tellurium, but is not limited thereto.

As used herein, “metal” comprises a semi-metal such as Si.

As used herein, a number of carbon atoms in a group or a molecule may be referred to as a subscript (e.g., C₆₋₅₀) or as C6-C50.

As used herein, when a definition is not otherwise provided, “substituted” refers to replacement of at least one hydrogen of a compound or a group with a corresponding substituent including a C1-C30 alkyl group, a C2-C30 alkenyl group, a C2-C30 alkynyl group, a C6-C30 aryl group, a C7-C30 alkylaryl group, a C1-C30 alkoxy group, a C1-C30 heteroalkyl group, a C3-C30 heteroaryl group, a C3-C30 cycloalkyl group, a C3-C15 cycloalkenyl group, a C6-C30 cycloalkynyl group, a C2-C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1-C6 alkyl group), an azido group (—N₃), an amidino group (—C(═NH)NH₂), a hydrazino group (—NHNH₂), a hydrazono group (═N(NH₂)), an aldehyde group (—C(═O) H), a carbamoyl group (—C(O)NH₂), a thiol group (—SH), an ester group (—C(═O) OR, wherein R is a C1-C6 alkyl group or a C6-C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence of greater than one formed by removal of one or more hydrogen atoms from an alkane, an alkene, an alkyne, or an arene group. In the hydrocarbon or hydrocarbon group, at least one, methylene may be replaced by an oxide moiety, a carbonyl moiety, an ester moiety, —NH—, or a combination thereof. Unless otherwise stated to the contrary, the hydrocarbon or the hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl, hexyl, etc.). In an embodiment, an alkyl group may have from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “aryl” refers to a group having a carbocyclic aromatic system. When the aryl group comprises a plurality of rings, the plurality of rings may be fused to each other. Examples include a phenyl group and a naphthyl group. In an embodiment, an aryl group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, P, Si, B, Se, Ge, Te, S, or a combination thereof.

As used herein, “heteroaryl” refers to an aromatic system having at least one N, O, P, Si, B, Se, Ge, Te, S, or a combination thereof as a ring forming atom. Examples of heteroaryl groups include a pyridinyl group, a pyrimidinyl group, a pyrazinyl group, a pyridazinyl group, a triazinyl group, a quinolinyl group, and an isoquinolinyl group. When the heteroaryl group comprises a plurality of rings, the plurality of rings may be fused to each other. In an embodiment, the heteroaryl group may have 3 to 50 carbon atoms, or 6 to 18 carbon atoms, or 6 to 12 carbon atoms.

As used herein, when a definition is not otherwise provided, “alkoxy” refers to an alkyl group linked to oxygen (e.g., alkyl-O—) for example, a methoxy group, an ethoxy group, or a sec-butyloxy group.

The term “cycloalkyl group” as used herein refers to a monovalent monocyclic saturated hydrocarbon group. Examples thereof include a cyclopropyl group, a cyclobutyl group, a cyclopentyl group, a cyclohexyl group, and a cycloheptyl group. In an embodiment, the cycloalkyl group may have 3 to 50 carbon atoms, or 3 to 18 carbon atoms, or 3 to 12 carbon atoms.

The term “heterocycloalkyl group” as used herein refers to a monovalent monocyclic group including at least one N, O, P, Si, B, Se, Ge, Te, S, or a combination thereof as a ring-forming atom in addition to the carbon atoms that are ring-forming atoms. Examples thereof include a tetrahydrofuranyl group and a tetrahydrothiophenyl group. In an embodiment, the heterocycloalkyl group may have 2 to 50 carbon atoms, or 2 to 18 carbon atoms, or 2 to 12 carbon atoms.

The term “cycloalkenyl group” as used herein refers to a monovalent monocyclic hydrocarbon group that has at least one carbon-carbon double bond in its ring, wherein the molecular structure as a whole is non-aromatic. Examples thereof include a cyclopentenyl group, a cyclohexenyl group, and a cycloheptenyl group. In an embodiment, the cycloalkenyl group may have 3 to 50 carbon atoms, or 3 to 18 carbon atoms, or 3 to 12 carbon atoms.

The term “heterocycloalkenyl group” as used herein refers to a monovalent monocyclic group including at least one N, O, P, Si, B, Se, Ge, Te, S, or a combination thereof as a ring-forming atom, and at least one double bond in its ring, wherein the molecular structure as a whole is non-aromatic. Examples of the heterocycloalkenyl group include a 2,3-dihydrofuranyl group and a 2,3-dihydrothiophenyl group. In an embodiment, the heterocycloalkenyl group may have 2 to 50 carbon atoms, or 2 to 18 carbon atoms, or 2 to 12 carbon atoms.

The term “arylalkyl group” refers to an alkyl group substituted with an aryl group. An example of an arylalkyl group is a benzyl group (i.e., —CH₂-phenyl).

The term “alkylaryl group” refers to an aryl group substituted with an alkyl group. An example of an alkylaryl group is a tolyl group.

As used herein, when a definition is not otherwise provided, “amine” is a compound represented by —NRR, wherein each R is independently hydrogen, a C1-C12 alkyl group, a C7-C20 alkylaryl group, a C7-C20 arylalkyl group, or a C6-C18 aryl group.

As used herein, the expression “not including cadmium (or other harmful heavy metal)” means that a concentration of cadmium (or another heavy metal deemed harmful) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or zero. In an embodiment, substantially no amount of cadmium (or other toxic heavy metal) may be present or, if present, an amount of cadmium (or other heavy metal) may be less than or equal to a detection limit or as an impurity level of a given analysis tool (e.g., an inductively coupled plasma atomic emission spectroscopy instrument).

Unless mentioned to the contrary, a numerical range recited herein is inclusive. Unless mentioned to the contrary, a numerical range recited herein comprises any real number within the endpoints of the stated range and comprises the endpoints thereof. In this specification, a numerical endpoint or an upper or lower limit value (e.g., recited either as a “greater than or equal to value” “at least value” or a “less than or equal to value” or recited with “from” or “to”) may be used to form a numerical range of a given feature. In other words, the upper and lower endpoints set forth for various numerical values may be independently combined to provide a range.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, ±5%, ±3%, or ±1% of the stated value.

As used herein, a nanoparticle is a structure having at least one region or characteristic dimension with a nanoscale dimension. In an embodiment, a dimension (or an average dimension) of the nanostructure is less than or equal to about 500 nanometers (nm), less than or equal to about 300 nm, less than or equal to about 250 nm, less than or equal to about 150 nm, less than or equal to about 100 nm, less than or equal to about 50 nm, or less than or equal to about 30 nm, and may be greater than about 0.1 nm or greater than about 1 nm. In an embodiment, the nanoparticle may have any suitable shape.

The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanodot, a multi-pod type shape such as at least two pods, or the like and is not limited thereto. The nanoparticle may be, e.g., substantially crystalline, substantially monocrystalline, polycrystalline, (for example, at least partially) amorphous, or a combination thereof.

In an embodiment, a semiconductor nanoparticle such as a quantum dot may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect. The semiconductor nanoparticle or the quantum dot may emit light corresponding to a bandgap energy thereof by controlling a size of a nanocrystal acting as an emission center.

As used herein, the term “T50” is a time (hours, h) taken until the brightness (e.g., luminance) of a given device decreases to 50% of the initial brightness (100%) as, e.g., when, the given device is started to be driven, e.g., operated, at a predetermined initial brightness (e.g., 650 nit).

As used herein, the term “T90” is a time (h) taken until the brightness (e.g., luminance) of a given device decreases to 90% of the initial brightness (100%) as the given device is started to be driven at a predetermined initial brightness (e.g., 650 nit).

As used herein, the phrase “external quantum efficiency (EQE)” is a ratio of the number of photons emitted from a light-emitting diode (LED) to the number of electrons passing through the device and may be a measurement as to how efficiently a given device converts electrons to photons and allows the photons to escape. The EQE may be determined by the following equation:

EQE=(efficiency of injection)×((solid-state)quantum yield)×(efficiency of extraction)
wherein the efficiency of injection is a proportion of electrons passing through the device that are injected into the active region, the quantum yield is a proportion of all electron-hole recombinations in the active region that are radiative and produce photons, and the efficiency of extraction is a proportion of photons generated in the active region that escape from the given device.

As used herein, a maximum EQE is a greatest value of the EQE.

As used herein, a maximum luminance is the highest value of luminance for a given device.

As used herein, the phrase “quantum efficiency” may be used interchangeably with the phrase, quantum yield. In an embodiment, the quantum efficiency may be a relative quantum yield or an absolute quantum yield, for example, which may be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as standard dye, depending on the photoluminescence (PL) wavelengths thereof, but are not limited thereto.

As used herein, the term “dispersion” refers to a dispersion in which a dispersed phase is a solid, and a continuous medium comprises a liquid or a solid different from the dispersed phase. In an embodiment, the ink composition may be in a form of a dispersion. Herein, the “dispersion” may be a colloidal dispersion in which the dispersed phase has a dimension of greater than or equal to about 1 nm, for example, greater than or equal to about 2 nm, greater than or equal to about 3 nm, or greater than or equal to about 4 nm to several micrometers (μm) or less, (e.g., less than or equal to about 2 μm, less than or equal to about 1 μm, less than or equal to about 900 nm, less than or equal to about 800 nm, less than or equal to about 700 nm, less than or equal to about 600 nm, or less than or equal to about 500 nm).

An energy bandgap of a semiconductor nanoparticle may vary depending on a size, a structure, and a composition of a nanocrystal. For example, a quantum dot may have a narrower energy bandgap as a size thereof increases, and an emission wavelength thereof may increase. A semiconductor nanocrystal has attracted attention as a light emitting material in various fields such as a display device, an energy device, or a bio-luminescent device. Meanwhile, semiconductor nanoparticles having electroluminescent properties at a level applicable to actual applications may include harmful heavy metals such as cadmium (Cd), lead, mercury, or a combination thereof. It is desirable to provide a semiconductor nanoparticle that emits light having a desired wavelength while substantially not including the harmful heavy metals. In addition, from an environmental point of view, provision of a light emitting device or a display device having a light emitting layer based on a semiconductor nanoparticle that does not include cadmium, which is a harmful heavy metal, may be desirable.

An inorganic-containing semiconductor nanoparticle is applied as a light emitting material in an electronic device, for example, an electroluminescent device. An electroluminescent device based on a semiconductor nanoparticle (e.g., a QD light emitting diode, QD-LED) utilizes electroluminescence of a semiconductor nanoparticle through injection and recombination of electrons and holes in a semiconductor nanoparticle such as a quantum dot, and has a high applicability to various electronic devices (e.g., a display device). The electroluminescent device based on a semiconductor nanoparticle does not require a separate backlight and may be provided in a thin structure. Studies to improve performance of an electroluminescent device by modifying a semiconductor nanoparticle are also actively conducted. Studies to provide such a QD-LED device by a low-cost solution process such as inkjet printing are also in progress.

A semiconductor nanoparticle comprises a ligand on a surface thereof. For example, a semiconductor nanoparticle may include a ligand having a double bond and a long carbon chain length, and in this case, the semiconductor nanoparticle may be well dissolved in a nonpolar solvent. However, the present inventors have found that such ligands present on the semiconductor nanoparticle may interfere with charge injection during driving of an electroluminescent device and may be disadvantageous in terms of device performance (efficiency and lifetime). A semiconductor nanoparticle having a ligand that does not have a double bond and has a short carbon chain length is considered to contribute to improvement of performance of an electroluminescent device including the same. However, the present inventors have also found that a quantum dot including such a ligand having a short carbon chain length has significantly reduced dispersibility in a specific solvent, for example, a high-boiling nonpolar solvent that can be employed in an ink composition for an inkjet process, such as cyclohexylbenzene.

According to an embodiment, a semiconductor nanoparticle prepared is treated according to the treatment method described herein and dispersed in a liquid vehicle for desired inkjet printing, thereby forming a light emitting device, for example, an electroluminescent device, through an inkjet printing process.

In an embodiment, a method for treating a semiconductor nanoparticle comprises:
adding zinc chloride to a first dispersion including a liquid medium (e.g., a liquid vehicle for inkjet printing) and a semiconductor nanoparticle dispersed in the liquid medium to precipitate the semiconductor nanoparticle to provide a precipitated semiconductor nanoparticle;
adding a ligand compound to the first dispersion and mixing the ligand compound with the first dispersion including the precipitated semiconductor nanoparticle to obtaining a second dispersion in which a semiconductor nanoparticle surface treated with the ligand compound is dispersed in the liquid medium to provide a surface-treated semiconductor nanoparticle; and
recovering the surface-treated semiconductor nanoparticle from the second dispersion.

The liquid medium may include one or more (e.g., a plurality of) organic solvents. The organic solvent may include the solvents described herein. The organic solvent may be an organic solvent having a relatively high boiling point at normal pressure or atmospheric pressure. A boiling point of the organic solvent or the liquid medium may be greater than or equal to about 120° C., greater than or equal to about 127° C., greater than or equal to about 129° C., greater than or equal to about 130° C., greater than or equal to about 135° C., greater than or equal to about 140° C., greater than or equal to about 145° C., greater than or equal to about 150° C., greater than or equal to about 155° C., greater than or equal to about 160° C., greater than or equal to about 165° C., greater than or equal to about 170° C., greater than or equal to about 175° C., or greater than or equal to about 180° C. The boiling point of the organic solvent may be less than or equal to about 400° C., less than or equal to about 380° C., less than or equal to about 370° C., less than or equal to about 360° C., less than or equal to about 350° C., less than or equal to about 340° C., less than or equal to about 330° C., less than or equal to about 320° C., less than or equal to about 310° C., less than or equal to about 300° C., less than or equal to about 280° C., less than or equal to about 270° C., less than or equal to about 250° C., or less than or equal to about 200° C.

The liquid medium or the organic solvent may include a substituted or unsubstituted C6 to C40 aromatic hydrocarbon solvent; a substituted or unsubstituted C6 to C15 aliphatic hydrocarbon solvent; a substituted or unsubstituted C6 to C50 amine solvent; or a combination thereof. The liquid medium or the organic solvent may include a substituted or unsubstituted aromatic hydrocarbon solvent of C6 to C40 or C12-C24 such as cyclohexylbenzene; a substituted or unsubstituted C6 to C15 aliphatic hydrocarbon solvent such as decane, nonane, or dodecane of C10 to C40 or C12-C24; an amine solvent of C6 to C50 such as trioctylamine or tridecylamine; or a combination thereof.

In an embodiment, the liquid medium or the organic solvent may use a mixed solvent including two or more kinds of organic solvents, and a mixing ratio thereof may be adjusted in consideration of conditions for an inkjet process (e.g., boiling point, viscosity) or reaction conditions described herein. For example, when a mixed solvent of an aromatic solvent and an aliphatic solvent is used, the mixing ratio may be adjusted to 1:0.1 to 1:10, 1:0.3 to 1:3, or 1:0.5 to 1:2 (volume:volume), but is not limited thereto.

The liquid medium or the organic solvent may include cyclohexylbenzene, trioctylamine, or a combination thereof.

In an embodiment, a semiconductor nanoparticle is a particle that comprises a semiconductor nanocrystal and may exhibit a quantum confinement effect. In an embodiment, the semiconductor nanoparticle may include zinc, selenium, and sulfur. The semiconductor nanoparticle may have a core-shell structure. The semiconductor nanoparticle or the core-shell structure may include a first semiconductor nanocrystal; and a semiconductor nanocrystal shell disposed on the first semiconductor nanocrystal and including zinc and sulfur (including a third semiconductor nanocrystal).

The semiconductor nanoparticle or the first semiconductor nanocrystal may include indium phosphide, indium zinc phosphide, zinc selenide, zinc telluride, zinc tellurium selenide, silver indium gallium sulfide, silver indium sulfide, or a combination thereof.

The semiconductor nanoparticle or the semiconductor nanocrystal shell may include a zinc selenide, a zinc selenide telluride, a zinc selenide sulfide, a zinc sulfide, or a combination thereof. The semiconductor nanocrystal shell may include a first shell layer (including a second semiconductor nanocrystal); and a second shell layer disposed on the first shell layer and including, for example, a third semiconductor nanocrystal. The first shell layer or the second semiconductor nanocrystal may include a zinc selenide, a zinc selenide telluride, a zinc selenide sulfide, or a combination thereof. The second shell layer or the third semiconductor nanocrystal may include a zinc selenide sulfide, a zinc sulfide, or a combination thereof. In an embodiment, a core-shell type semiconductor nanoparticle may include a semiconductor nanocrystal shell on a first semiconductor nanocrystal (or a core including the same). Depending on the compositions of the first semiconductor nanocrystal and the semiconductor nanocrystal shell, the semiconductor nanoparticle may have an energy band alignment such as type I, type II, or quasi type II, and may be configured to emit light of a desired wavelength upon application of a voltage.

In an embodiment, the semiconductor nanoparticle, the first semiconductor nanocrystal, or the semiconductor nanocrystal shell (for example, a second semiconductor nanocrystal or a third semiconductor nanocrystal) may each independently include a Group II-VI compound, a Group III-V compound, a Group IV-VI compound, a Group IV element or compound, a Group II-III-VI compound, a Group I-III-VI compound, a Group I-II-IV-VI compound, or a combination thereof.

The Group II-VI compound may include a binary compound selected from CdS, CdSe, CdTe, CdO, ZnS, ZnSe, ZnTe, ZnO, HgS, HgSe, HgTe, MgSe, MgS, and a mixture thereof; a ternary compound selected from CdSeS, CdSeTe, CdSTe, ZnSeS, ZnSeTe, ZnSTe, HgSeS, HgSeTe, HgSTe, HgZnS, HgZnSe, HgZnTe, MgZnSe, MgZnS, and a mixture thereof; a quaternary compound selected from HgZnTeS, HgZnSeS, HgZnSeTe, HgZnSTe, and a mixture thereof; or a combination thereof. The Group II-VI compound may further include a Group III metal.

The Group III-V compound may include a binary compound selected from GaN, GaP, GaAs, GaSb, AlN, AlP, AlAs, AlSb, InN, InP, InAs, InSb, and a mixture thereof, a ternary compound selected from GaNP, GaNAs, GaNSb, GaPAs, GaPSb, AlNP, AlNAs, AlNSb, AlPAs, AlPSb, InNP, InNAs, InNSb, InPAs, InPSb, and a mixture thereof; a quaternary compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or a combination thereof. The Group III-V compound may further include a Group II element. An example of such a semiconductor nanocrystal comprises InZnP.

The Group IV-VI compound may include a binary compound selected from SnS, SnSe, SnTe, and a mixture thereof; a ternary compound selected from SnSeS, SnSeTe, SnSTe, and a mixture thereof; a quaternary compounds such as SnSSeTe; or a combination thereof.

Examples of the Group I-III-VI compound include, but are not limited to, CuInSe₂, CuInS₂, CuInGaSe, and CuInGaS. Examples of the Group I-III-VI semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂; a quaternary compound such as AgInGaS₂ or AgInGaSe₂; or a combination thereof.

Examples of the Group I-II-IV-VI compound include, but are not limited to, CuZnSnSe and CuZnSnS.

The Group IV element or compound may include a single element selected from Si and Ge; a binary compound selected from SiC, SiGe, and a mixture thereof, or a combination thereof.

Each element included in a multinary compound such as the binary compound, the ternary compound, and the quaternary compound may be present in a particle at a uniform concentration or a non-uniform concentration. For example, the chemical formula denotes the type of element included in the compound, and an element ratio in the compound may vary. For example, AgInGaS₂ may include AgInₓGa₁₋ₓS₂ (x is a real number of greater than or equal to about 0 and less than or equal to about 1), but is not limited thereto.

In an embodiment, the first semiconductor nanocrystal may include a metal including indium, zinc, or a combination thereof, and a nonmetal including phosphorus, selenium, tellurium, sulfur, or a combination thereof. In an embodiment, the second semiconductor nanocrystal may include a metal including indium, zinc, or a combination thereof, and a nonmetal element including phosphorus, selenium, tellurium, sulfur, or a combination thereof.

In an embodiment, the first semiconductor nanocrystal may include InP, InZnP, ZnSe, ZnSeS, ZnSeTe, or a combination thereof, and/or the second semiconductor nanocrystal may include ZnSe, ZnSeS, ZnS, ZnTeSe, or a combination thereof. In an embodiment, the shell may include, for example, at an outermost layer, zinc, sulfur, and optionally selenium.

In an embodiment, semiconductor nanoparticles emit blue light or green light and may have a core including ZnSeTe, ZnSe, or a combination thereof, and a shell including a zinc chalcogenide (e.g., ZnS, ZnSe, and/or ZnSeS). In the shell, an amount of sulfur may increase or decrease in a radial direction (from the core toward a surface).

In an embodiment, semiconductor nanoparticles emit red light or green light, the core comprises InP, InZnP, or a combination thereof, and the shell may include a Group II metal including zinc and a nonmetal including at least one of sulfur and selenium.

In an embodiment, when the semiconductor nanoparticles have a core-shell structure, an alloyed layer may be present or may not be present at an interface between the core and the shell. The alloyed layer may be a homogeneous alloy or may be a gradient alloy. In the gradient alloy, a concentration of an element present in the shell may have a concentration gradient that changes in a radial direction (for example, decreasing or increasing toward a center).

In an embodiment, the shell may have a composition that changes in a radial direction. In an embodiment, the shell may be a multilayer shell including two or more layers. In the multilayer shell, two adjacent layers may have different compositions from each other. In the multilayer shell, one or more layers may each independently include semiconductor nanocrystals having a single composition. In the multilayer shell, one or more layers may each independently include alloyed semiconductor nanocrystals. In the multilayer shell, one or more layers may have a concentration gradient that changes in a radial direction in terms of a composition of the semiconductor nanocrystals.

In a semiconductor nanoparticle having a core-shell structure, a bandgap energy of a shell material may be greater than that of a core material, but is not limited thereto. The bandgap energy of the shell material may be smaller than that of the core material. In the case of a multilayer shell, an outermost layer material may have a larger energy bandgap than materials of the core and inner layers of the shell (that is, layers closer to the core). In the multilayer shell, a bandgap of semiconductor nanocrystals of each layer may be appropriately selected to efficiently exhibit a quantum confinement effect.

In an embodiment, a semiconductor nanoparticle may adjust an absorption/emission wavelength, for example, by controlling a composition and/or a size thereof. The semiconductor nanoparticle included in the emission layer (or a light-emitting layer) 3 or 30 may be configured to emit light of a desired color. The semiconductor nanoparticle may include a blue light-emitting semiconductor nanoparticle, a green light-emitting semiconductor nanoparticle, or a red light-emitting semiconductor nanoparticle.

In an embodiment, a peak emission wavelength of light emitted from a semiconductor nanoparticle, an emission layer including the same, or an electroluminescent device may have a wavelength range from ultraviolet to infrared or a wavelength range greater than that. In an embodiment, the peak emission wavelength of light emitted from the semiconductor nanoparticle, the emission layer including the same, or the electroluminescent device may be greater than or equal to about 300 nm, for example, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The peak emission wavelength may be less than or equal to about 800 nm, for example, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The peak emission wavelength may be in a range of about 500 nm to about 650 nm.

A semiconductor nanoparticle, an emission layer including the same, or an electroluminescent device may emit green light, and a peak emission wavelength may be greater than or equal to about 500 nm (for example, greater than or equal to about 510 nm or greater than or equal to about 520 nm) and less than or equal to about 560 nm (for example, less than or equal to about 540 nm or less than or equal to about 530 nm). The semiconductor nanoparticle, the emission layer including the same, or the electroluminescent device may emit red light, and a peak emission wavelength may be greater than or equal to about 600 nm (for example, greater than or equal to about 610 nm) and less than or equal to about 650 nm (for example, less than or equal to about 640 nm). The semiconductor nanoparticle, the emission layer including the same, or the electroluminescent device may emit blue light, and a peak emission wavelength may be greater than or equal to about 440 nm (for example, greater than or equal to about 450 nm or greater than or equal to about 455 nm) and less than or equal to about 480 nm (for example, less than or equal to about 470 nm or less than or equal to about 465 nm).

The semiconductor nanoparticle, the emission layer including the same, or the electroluminescent device may exhibit an emission spectrum (a photoluminescence spectrum or an electroluminescence spectrum) having a relatively narrow full width at half maximum. In an embodiment, the semiconductor nanoparticle, the emission layer, or the electroluminescent device may have, in the emission spectrum thereof, a full width at half maximum that is less than or equal to about 45 nm, for example, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm. The full width at half maximum may be greater than or equal to about 10 nm, greater than or equal to about 15 nm, greater than or equal to about 20 nm, or greater than or equal to about 25 nm.

The semiconductor nanoparticle may have a quantum yield of greater than or equal to about 10%, for example, greater than or equal to about 20%, greater than or equal to about 30%, greater than or equal to about 40%, greater than or equal to about 50%, greater than or equal to about 60%, greater than or equal to about 70%, greater than or equal to about 80%, greater than or equal to about 90%, or even about 100% (e.g., be configured to exhibit such a quantum yield). In an embodiment, the semiconductor nanoparticle may have a quantum yield (or an absolute quantum yield) of greater than or equal to about 91%, greater than or equal to about 92%, greater than or equal to about 93%, greater than or equal to about 94%, greater than or equal to about 95%, greater than or equal to about 96%, or greater than or equal to about 97%.

A semiconductor nanoparticle may have a size or an average size (hereinafter, abbreviated as a size) of greater than or equal to about 1 nm and less than or equal to about 100 nm. The size of the semiconductor nanoparticle may be, for example, a particle diameter, or in the case of a non-spherical particle, an equivalent particle diameter. The particle diameter or the equivalent particle diameter may be calculated from a two-dimensional area confirmed by electron microscopy analysis. In an embodiment, the semiconductor nanoparticle may have a size of about 1 nm to about 50 nm, for example, about 2 nm (or about 3 nm) to about 35 nm. In an embodiment, the size of the semiconductor nanoparticle may be greater than or equal to about 1 nm, greater than or equal to about 2 nm, greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, or greater than or equal to about 14 nm. In an embodiment, the size of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, or less than or equal to about 15 nm.

The semiconductor nanoparticle may have any shape. In an embodiment, the shape of the semiconductor nanoparticle may include a sphere, a polyhedron, a pyramid, a multipod, a cubic shape, a nanotube, a nanowire, a nanofiber, a nanosheet, a nanoplate, or a combination thereof.

The semiconductor nanoparticle may be synthesized by any method. In an embodiment, the semiconductor nanoparticle may be synthesized by a method described herein. The method of an embodiment may synthesize a semiconductor nanocrystal having a size of several nanometers through a wet chemical process. In the wet chemical process, precursor materials are reacted in an organic solvent to grow crystal particles, and an organic solvent or a ligand compound may coordinate to a surface of the semiconductor nanocrystal to control growth of the crystal. In an embodiment, a method of preparing the semiconductor nanoparticle may include preparing a particle including a first semiconductor nanocrystal and, optionally, a second semiconductor nanocrystal and/or a third semiconductor nanocrystal.

Details relating to the first semiconductor nanocrystal, the second semiconductor nanocrystal, and the third semiconductor nanocrystal are as described herein. In the method of an embodiment, when present, the second semiconductor nanocrystal may include zinc and selenium (e.g., ZnSe, ZnSeS, or a combination thereof). The second semiconductor nanocrystal may be disposed on the first semiconductor nanocrystal. The second semiconductor nanocrystal may be an intermediate shell layer of a semiconductor nanoparticle. The third semiconductor nanocrystal may include zinc and sulfur.

In the method of an embodiment, preparation of a particle including the first semiconductor nanocrystal and, optionally, the second or the third semiconductor nanocrystal is not particularly limited and may be appropriately selected.

In an embodiment, the first semiconductor nanocrystal or a core including the same may include zinc and selenium and, optionally, tellurium. The first semiconductor nanocrystal or the core including the same may include indium and phosphorus. The first semiconductor nanocrystal or the core including the same may include ZnSe, ZnSeTe, InP, InZnP, or a combination thereof. In an embodiment, the first semiconductor nanocrystal or the core including the same may be prepared by an appropriate method in consideration of a composition thereof and desired properties of a final nanoparticle, or may be commercially available.

In an embodiment, the first semiconductor nanocrystal or the core including the same may include a zinc chalcogenide including zinc, selenium, and tellurium, and the first semiconductor nanocrystal or the core may be obtained by preparing a zinc precursor solution including a zinc precursor and an organic ligand; preparing a selenium precursor and a tellurium precursor; heating the zinc precursor solution to a core formation reaction temperature; and adding the selenium precursor and, optionally, the tellurium precursor together with an organic ligand and proceeding with a core formation reaction.

In an embodiment, the first semiconductor nanocrystal or the core including the same may be formed by a hot injection method in which a phosphorus precursor is injected while a solution including a metal precursor such as an indium precursor and, optionally, a ligand is heated to a high temperature (for example, a temperature of greater than or equal to about 200° C.). In an embodiment, the core may be prepared by a heating up method in which a phosphorus precursor is injected at a predetermined temperature and a temperature of a reaction system is increased.

In a core formation reaction, a ratio between respective precursors (for example, a mole ratio of a tellurium precursor to a selenium precursor) and/or a reaction time may be appropriately selected in consideration of an emission wavelength of a final semiconductor nanoparticle, reactivity of the precursors, a reaction temperature, and the like. A core formation reaction temperature may be appropriately selected. The core formation reaction temperature may be greater than or equal to about 240° C., greater than or equal to about 250° C., greater than or equal to about 260° C., greater than or equal to about 270° C., greater than or equal to about 280° C., for example, greater than or equal to about 290° C. The reaction temperature for core formation may be in a range of about 280° C. to about 340° C., for example, about 290° C. to about 330° C., or about 300° C. to about 320° C. A reaction time for core formation may be adjusted in consideration of a desired core size and reactivity of the precursors and is not particularly limited. For example, the reaction time may be greater than or equal to about 5 minutes, greater than or equal to about 30 minutes, or greater than or equal to about 50 minutes, but is not limited thereto. For example, the reaction time may be less than or equal to about 2 hours, but is not limited thereto. A formed core may be separated from a reaction system (for example, by nonsolvent precipitation) or may not be separated. The separated core may, optionally after washing, be added to a subsequent reaction.

A semiconductor nanoparticle of an embodiment may further include a second semiconductor nanocrystal or an intermediate shell including the same, and a method of forming the second semiconductor nanocrystal or the intermediate shell layer including the same is not particularly limited and may be appropriately selected.

In the method of an embodiment, forming the second semiconductor nanocrystal (or the intermediate shell layer including the same) on the first semiconductor nanocrystal comprises contacting (reacting) a zinc precursor and a chalcogen precursor (for example, a selenium precursor and, optionally, a sulfur precursor) at a reaction temperature in the presence of an organic solvent and the first semiconductor nanocrystal.

An organic ligand, an organic solvent, and precursors are not particularly limited and may be appropriately selected.

The organic solvent may include a C6-C22 primary amine such as a hexadecylamine, a C6-C22 secondary amine such as dioctylamine, a C6-C40 tertiary amine such as a trioctyl amine, a nitrogen-containing heterocyclic compound such as pyridine, a C6-C40 olefin such as octadecene, a C6-C40 aliphatic hydrocarbon such as hexadecane, octadecane, or squalane, an aromatic hydrocarbon substituted with a C6-C30 alkyl group such as phenyldodecane, phenyltetradecane, or phenyl hexadecane, a primary, secondary, or tertiary phosphine (e.g., trioctyl phosphine) substituted with at least one (e.g., 1, 2, or 3) C6-C22 alkyl group, a phosphine oxide (e.g. trioctylphosphine oxide) substituted with a (e.g., 1, 2, or 3) C6-C22 alkyl group, a C12-C22 aromatic ether such as phenyl ether or benzyl ether, or a combination thereof.

The organic ligand may coordinate the surfaces of the prepared semiconductor nanoparticles and allow the semiconductor nanoparticles to be well dispersed in the solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH (wherein R and R′ independently include substituted or unsubstituted C1 or more, C6 or more, or C10 or more and C40 or less, C35 or less, or C25 or less aliphatic hydrocarbon group, or substituted or unsubstituted C6-C40 aromatic hydrocarbon group, or a combination thereof), or a combination thereof. The ligands may be used alone or as a combination of two or more compounds.

A type of the indium precursor is not particularly limited and may be selected appropriately. The indium precursor may include an indium powder, an alkylated indium compound, an indium alkoxide, an indium carboxylate, an indium nitrate, an indium perchlorate, an indium sulfate, an indium acetylacetonate, an indium halide, an indium cyanide, an indium hydroxide, an indium oxide, an indium peroxide, an indium carbonate, an indium acetate, or a combination thereof. The indium precursor may include an indium carboxylate such as indium oleate and indium myristate, an indium acetate, an indium hydroxide, an indium chloride, an indium bromide, an indium iodide, or a combination thereof. In an embodiment, formation of an indium precursor may be performed under vacuum at a temperature of greater than or equal to about 100° C., greater than or equal to about 120° C., and less than or equal to about 200° C.

A type of a phosphorus precursor is not particularly limited and may be appropriately selected. The phosphorus precursor may include tris(trimethylsilyl)phosphine, tris(dimethylamino)phosphine, triethylphosphine, tributylphosphine, trioctylphosphine, triphenylphosphine, tricyclohexylphosphine, dimethylaminophosphine, diethylaminophosphine, or a combination thereof.

Examples of the organic ligand may include methane thiol, ethane thiol, propane thiol, butane thiol, pentane thiol, hexane thiol, heptane thiol, octane thiol, nonanethiol, decanethiol, dodecane thiol, hexadecane thiol, octadecane thiol, benzyl thiol; methyl amine, ethyl amine, propyl amine, butyl amine, pentyl amine, hexyl amine, octyl amine, dodecyl amine, hexadecyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; substituted or unsubstituted methyl phosphine (e.g., trimethyl phosphine, methyldiphenyl phosphine, or the like), substituted or unsubstituted ethyl phosphine (e.g., triethyl phosphine, ethyldiphenyl phosphine, or the like), substituted or unsubstituted propyl phosphine, substituted or unsubstituted butyl phosphine, substituted or unsubstituted pentyl phosphine, substituted or unsubstituted octylphosphine (e.g., trioctylphosphine (TOP)), or the like; a phosphine oxide such as substituted or unsubstituted methyl phosphine oxide (e.g., trimethyl phosphine oxide, methyldiphenylphosphine oxide, or the like), substituted or unsubstituted ethyl phosphine oxide (e.g., triethyl phosphine oxide, ethyldiphenyl phosphine oxide, or the like), substituted or unsubstituted propyl phosphine oxide, substituted or unsubstituted butyl phosphine oxide, substituted or unsubstituted octylphosphine oxide (e.g., trioctylphosphine oxide (TOPO), or the like); diphenyl phosphine, a triphenyl phosphine, or an oxide compound thereof; a C5-C20 alkylphosphinic acid such as hexylphosphinic acid, octylphosphinic acid, dodecanephosphinic acid, tetradecanephosphinic acid, hexadecanephosphinic acid, or octadecanephosphinic acid; a C5-C20 alkyl phosphonic acid; or the like, but embodiments are not limited thereto. The organic ligand may be used alone or as a combination of two or more.

The zinc precursor may be a Zn metal powder, ZnO, an alkylated Zn compound (e.g., a C2-C30 dialkyl zinc such as diethyl zinc), a Zn alkoxide (e.g., a zinc ethoxide), a Zn carboxylate (e.g., a zinc acetate), a Zn nitrate, a Zn perchlorate, a Zn sulfate, Zn acetylacetonate, a Zn halide (e.g., a zinc chloride), a Zn cyanide, a Zn hydroxide, a Zn carbonate, a Zn peroxide, or a combination thereof. Examples of the zinc precursor may be dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof.

The selenium precursor may include selenium-trioctylphosphine (“Se-TOP”), selenium-tributylphosphine (“Se-TBP”), selenium-triphenylphosphine (“Se-TPP”), selenium-diphenylphosphine (“Se-DPP”), or a combination thereof, but is not limited thereto.

The tellurium precursor may include tellurium-tributylphosphine (“Te-TBP”), tellurium-triphenylphosphine (“Te-TPP”), tellurium-diphenylphosphine (“Te-DPP”), or a combination thereof, but is not limited thereto.

The sulfur precursor may be hexane thiol, octane thiol, decane thiol, dodecane thiol, hexadecane thiol, mercapto propyl silane, sulfur-trioctylphosphine (“S-TOP”), sulfur-tributylphosphine (“S-TBP”), sulfur-triphenylphosphine (“S-TPP”), sulfur-trioctylamine (“S-TOA”), a bis(trialkylsilyl) sulfide, a bis(trialkylsilylalkyl) sulfide e.g., bis(trimethylsilylmethyl) sulfide, ammonium sulfide, sodium sulfide, or a combination thereof.

In an embodiment, formation of a third semiconductor nanocrystal may be performed in a one pot manner after formation of a second semiconductor nanocrystal. In an embodiment, a particle including a first semiconductor nanocrystal and, optionally, a second semiconductor nanocrystal may, after synthesis, be separated and washed according to a method described herein before being introduced into a subsequent reaction (for example, a reaction for forming a semiconductor nanocrystal shell including zinc and sulfur). The separated and washed particle may be dispersed in an appropriate organic solvent (for example, an aromatic solvent such as toluene or an aliphatic hydrocarbon solvent such as octane) and then added to a subsequent reaction.

In an embodiment, a method of manufacturing a semiconductor nanoparticle comprises, in the presence of the particle including the first semiconductor nanocrystal and, optionally, the second semiconductor nanocrystal, contacting (for example, reacting) a zinc precursor (for example, a zinc carboxylate) and a sulfur precursor in a reaction medium including an organic solvent; and, optionally, adding a metal halide to the reaction medium. By the reaction, a shell layer including zinc and sulfur (a semiconductor nanocrystal shell layer) may be formed on the particle.

In an embodiment, the zinc precursor and the sulfur precursor may be selected from those described above.

In another embodiment, the zinc precursor (a zinc carboxylate) may include a first zinc precursor (for example, a first zinc carboxylate) including a short-chain organic ligand and a zinc ion, and a second zinc precursor (for example, a second zinc carboxylate) including a long-chain organic ligand and a zinc ion. According to such a method, a ligand system disposed on a surface of the semiconductor nanoparticle may be more precisely controlled. In formation of the shell layer including zinc and sulfur, the semiconductor nanoparticle prepared by this method may exhibit desired dispersibility for a subsequent emission layer formation process and may provide improved properties and lifetime in an electroluminescent device. Without wishing to be bound by any theory, a zinc precursor having a long-chain carboxylate (for example, the second zinc precursor) may exhibit a significant difference in dissociation constant (pKa, or acidity coefficient) from the first zinc precursor, and a combination of such zinc precursors may contribute not only to uniform growth of a ZnS shell layer but also to optimization of a total organic content of a ligand system disposed at an outermost layer, thereby exhibiting improved properties during driving of an electroluminescent device and preventing device degradation to contribute to lifetime extension.

In formation of a ZnS shell, details regarding the organic solvent and the sulfur precursor are as described herein. The sulfur precursor used for formation of the ZnS shell layer is as described herein. In the method of an embodiment, the sulfur precursor may include a thiol compound (for example, a monothiol compound having a C1 to C30 or C5 to C24 or C8 to C12 alkyl group, such as dodecanethiol).

In an embodiment, a first zinc precursor may include a short-chain organic ligand and a zinc ion, and may be obtained by a reaction between a carboxylic acid corresponding to the short-chain organic ligand (hereinafter, a first carboxylic acid) and an appropriate zinc compound (for example, zinc acetate). A second zinc precursor may include a long-chain organic ligand and a zinc ion, and may be obtained by a reaction between a carboxylic acid corresponding to the long-chain organic ligand (hereinafter, a second carboxylic acid) and an appropriate zinc compound (for example, zinc acetate). The appropriate zinc compound may include a zinc precursor exemplified in core formation and ZnSe formation. Details regarding the long-chain organic ligand and the short-chain organic ligand may be referred to those described for a second organic ligand and a first organic ligand, respectively.

The first carboxylic acid is a carboxylic acid including the short-chain organic ligand. In an embodiment, the first carboxylic acid may be represented by Chemical formula 2:

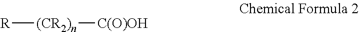

wherein each R is the same or different and is each independently hydrogen or a C1-C6, or C2-C4, or C3-C5 alkyl group (e.g., methyl group, ethyl group, propyl group, butyl group, pentyl group, or hexyl group), and n is an integer of 1 to 14, or 2 to 12, or 3 to 10, or 4 to 8.

The first carboxylic acid may have a pKa of greater than or equal to about 4.8, greater than or equal to about 4.9, greater than or equal to about 5.5, greater than or equal to about 5.8, greater than or equal to about 6.5, or greater than or equal to about 7. The first carboxylic acid may have a pKa lower than that of a second carboxylic acid. In an embodiment, the first carboxylic acid may have a pKa of less than or equal to about 9, less than or equal to about 8.8, less than or equal to about 8.3, less than or equal to about 7.5, less than or equal to about 6.7, less than or equal to about 5.8, or less than or equal to about 4.9.

Examples of the first carboxylic acid may include propanoic acid, pentanoic acid, hexanoic acid, octanoic acid, ethylhexanoic acid, nonanoic acid, decanoic acid, dodecanoic acid, myristic acid, palmitic acid, ethylbutyric acid, propylvaleric acid, methylbutyric acid, butyloctanoic acid, or a combination thereof.

A second carboxylic acid is a carboxylic acid including the long-chain organic ligand. In an embodiment, examples of the second carboxylic acid may include linolenic acid, linoleic acid, oleic acid, elaidic acid, stearic acid, myristic acid, palmitic acid, or a combination thereof. The second carboxylic acid may have a pKa of greater than or equal to about 8.9, greater than or equal to about 9, greater than or equal to about 9.1, greater than or equal to about 9.8, greater than or equal to about 10, greater than or equal to about 10.1, or greater than or equal to about 10.14.

In an embodiment, a first zinc precursor may have the following structure, but is not limited thereto:

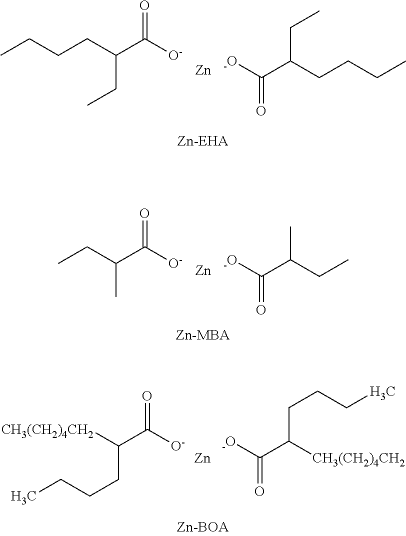

In an embodiment, a second zinc precursor may have the following structure, but is not limited thereto:

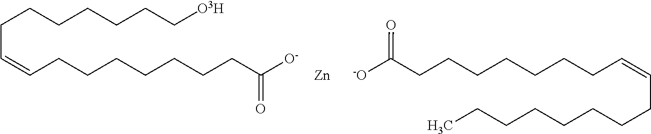

The metal halide may include a zinc halide, an aluminum halide, or a combination thereof. The zinc halide may include zinc chloride, zinc fluoride, zinc bromide, zinc iodide, or a combination thereof. The aluminum halide may include aluminum chloride, aluminum bromide, aluminum fluoride, aluminum iodide, or a combination thereof.

In an embodiment, in the method, a reaction medium including an organic solvent; and optionally an organic ligand may be subjected to vacuum treatment. The organic ligand is as described herein. The vacuum treatment may include heating the solvent and, optionally, a ligand compound to a predetermined temperature (for example, greater than or equal to about 100° C.) under vacuum (or performing vacuum treatment). The vacuum-treated reaction medium may be switched to an inert gas atmosphere and reheated to a predetermined temperature (for example, greater than or equal to about 120° C. or a reaction temperature).

In an embodiment, the particles and the sulfur precursor may be added to the reaction medium heated to the predetermined temperature. In an embodiment, after the first zinc precursor is added to the reaction medium (one time or two times or more) and comes into contact with the sulfur precursor, the second zinc precursor may be added to the reaction medium to come into contact with the sulfur precursor. In an embodiment, in the method, after the second zinc precursor is added to the reaction medium (one time or two times or more) and first comes into contact with the sulfur precursor, the first zinc precursor may be added to the reaction medium to come into contact with the sulfur precursor.

The first zinc precursor may be added to the reaction medium in a predetermined amount two times or more. The second zinc precursor may be added portionwise to the reaction medium two times or more.

In an embodiment, the metal halide may be added to the reaction medium after the first zinc precursor or the second zinc precursor comes into contact with the sulfur precursor.

In an embodiment, in the method, after the first zinc precursor first comes into contact with the sulfur precursor, the second zinc precursor may come into contact with the sulfur precursor, and the second zinc precursor may be added and mixed (admixing) into the reaction medium before addition of the metal halide, simultaneously with addition of the metal halide, or after addition of the metal halide. In an embodiment, in the method, after the second zinc precursor first comes into contact with the sulfur precursor, the first zinc precursor may come into contact with the sulfur precursor, and the first zinc precursor may be added and mixed (admixing) into the reaction medium before addition of the metal halide, simultaneously with addition of the metal halide, or after addition of the metal halide.

In an embodiment, in the method, an amount of the second zinc precursor relative to 1 mole of the first zinc precursor may be greater than or equal to about 0.01 mole, greater than or equal to about 0.03 mole, greater than or equal to about 0.05 mole, greater than or equal to about 0.07 mole, greater than or equal to about 0.09 mole, greater than or equal to about 0.1 mole, greater than or equal to about 0.2 mole, greater than or equal to about 0.3 mole, greater than or equal to about 0.4 mole, greater than or equal to about 0.5 mole, greater than or equal to about 0.6 mole, greater than or equal to about 0.7 mole, greater than or equal to about 0.8 mole, greater than or equal to about 0.9 mole, greater than or equal to about 1 mole, greater than or equal to about 1.2 mole, greater than or equal to about 1.5 mole, greater than or equal to about 1.7 mole, greater than or equal to about 1.9 mole, greater than or equal to about 2 mole, greater than or equal to about 2.1 mole, greater than or equal to about 2.3 mole, greater than or equal to about 2.5 mole, greater than or equal to about 2.7 mole, greater than or equal to about 2.9 mole, greater than or equal to about 3 mole, greater than or equal to about 3.5 mole, greater than or equal to about 4 mole, greater than or equal to about 4.5 mole, greater than or equal to about 5 mole, greater than or equal to about 5.5 mole, greater than or equal to about 6 mole, greater than or equal to about 6.5 mole, greater than or equal to about 7 mole, greater than or equal to about 7.5 mole, greater than or equal to about 8 mole, greater than or equal to about 8.5 mole, greater than or equal to about 9 mole, greater than or equal to about 9.5 mole, greater than or equal to about 10 mole, greater than or equal to about 50 mole, or greater than or equal to about 100 mole.

In an embodiment, in the method, the amount of the second zinc precursor relative to 1 mole of the first zinc precursor may be less than or equal to about 100 mole, less than or equal to about 90 mole, less than or equal to about 80 mole, less than or equal to about 70 mole, less than or equal to about 60 mole, less than or equal to about 50 mole, less than or equal to about 40 mole, less than or equal to about 30 mole, less than or equal to about 20 mole, less than or equal to about 10 mole, less than or equal to about 9 mole, less than or equal to about 8 mole, less than or equal to about 7 mole, less than or equal to about 6 mole, less than or equal to about 5 mole, less than or equal to about 4 mole, less than or equal to about 3 mole, less than or equal to about 2 mole, less than or equal to about 1 mole, less than or equal to about 0.8 mole, less than or equal to about 0.6 mole, less than or equal to about 0.4 mole, less than or equal to about 0.3 mole, less than or equal to about 0.2 mole, less than or equal to about 0.06 mole, or less than or equal to about 0.03 mole.

In an embodiment, in the method, an amount of the metal halide may be greater than or equal to about 0.01 moles, greater than or equal to about 0.03 moles, greater than or equal to about 0.04 moles, greater than or equal to about 0.05 moles, greater than or equal to about 0.07 moles, greater than or equal to about 0.09 moles, greater than or equal to about 0.1 moles, greater than or equal to about 0.12 moles, greater than or equal to about 0.14 moles, greater than or equal to about 0.16 moles, greater than or equal to about 0.18 moles, greater than or equal to about 0.2 moles, greater than or equal to about 0.21 moles, greater than or equal to about 0.23 moles, greater than or equal to about 0.25 moles, greater than or equal to about 0.27 moles, greater than or equal to about 0.29 moles, greater than or equal to about 0.3 moles, greater than or equal to about 0.35 moles, greater than or equal to about 0.4 moles, greater than or equal to about 0.45 moles, greater than or equal to about 0.5 moles, greater than or equal to about 0.55 moles, greater than or equal to about 0.6 moles, greater than or equal to about 0.65 moles, greater than or equal to about 0.7 moles, greater than or equal to about 0.75 moles, greater than or equal to about 0.8 moles, greater than or equal to about 0.85 moles, greater than or equal to about 0.9 moles, greater than or equal to about 0.95 moles, greater than or equal to about 1 mole, greater than or equal to about 5 moles, greater than or equal to about 10 moles, greater than or equal to about 50 moles, or greater than or equal to about 100 moles, per 1 mole of a total zinc precursor (that is, a total sum of the first zinc precursor and the second zinc precursor).

In an embodiment, in the method, an amount of the metal halide may be less than or equal to about 100 moles, less than or equal to about 90 moles, less than or equal to about 80 moles, less than or equal to about 70 moles, less than or equal to about 40 moles, less than or equal to about 10 moles, less than or equal to about 3 moles, less than or equal to about 1 mole, less than or equal to about 0.96 moles, less than or equal to about 0.84 moles, less than or equal to about 0.72 moles, less than or equal to about 0.63 moles, less than or equal to about 0.58 moles, less than or equal to about 0.52 moles, less than or equal to about 0.49 moles, less than or equal to about 0.43 moles, less than or equal to about 0.41 moles, less than or equal to about 0.4 moles, less than or equal to about 0.38 moles, less than or equal to about 0.34 moles, less than or equal to about 0.28 moles, less than or equal to about 0.26 moles, less than or equal to about 0.24 moles, less than or equal to about 0.22 moles, less than or equal to about 0.2 moles, less than or equal to about 0.19 moles, less than or equal to about 0.17 moles, less than or equal to about 0.15 moles, less than or equal to about 0.13 moles, less than or equal to about 0.11 moles, less than or equal to about 0.08 moles, less than or equal to about 0.06 moles, or less than or equal to about 0.03 moles, per 1 mole of a total zinc precursor (i.e., a total of the first zinc precursor and the second zinc precursor).

The predetermined temperature or the reaction temperature may be appropriately selected. In an embodiment, after heating the vacuum-treated reaction medium to a first temperature and adding the first semiconductor nanocrystal, the first zinc precursor (or the second zinc precursor), and the sulfur precursor, the reaction medium may be raised to the reaction temperature. The first temperature may be lower than the reaction temperature. A difference between the first temperature and the reaction temperature may be in a range of greater than or equal to about 80° C. to less than or equal to about 250° C., greater than or equal to about 80° C. to less than or equal to about 200° C., greater than or equal to about 120° C. to less than or equal to about 180° C., greater than or equal to about 140° C. to less than or equal to about 160° C., or a combination thereof.

The reaction temperature may be greater than or equal to about 250° C., greater than or equal to about 260° C., greater than or equal to about 270° C., greater than or equal to about 280° C., greater than or equal to about 300° C., greater than or equal to about 320° C., greater than or equal to about 340° C., or greater than or equal to about 350° C. The reaction temperature may be less than or equal to about 400° C., less than or equal to about 390° C., less than or equal to about 380° C., less than or equal to about 370° C., less than or equal to about 360° C., less than or equal to about 350° C., less than or equal to about 345° C., less than or equal to about 340° C., less than or equal to about 330° C., less than or equal to about 320° C., less than or equal to about 310° C., less than or equal to about 290° C., less than or equal to about 280° C., less than or equal to about 270° C., or less than or equal to about 250° C. In the method of an embodiment, the reaction temperature may vary within a range of greater than or equal to about 250° C. to less than or equal to about 340° C.

A reaction time may be appropriately selected in consideration of a type of the precursor, the reaction temperature, a desired thickness of a ZnS shell layer in a final semiconductor nanoparticle, and the like. The reaction time may be greater than or equal to about 10 minutes, greater than or equal to about 15 minutes, greater than or equal to about 20 minutes, greater than or equal to about 25 minutes, greater than or equal to about 30 minutes, greater than or equal to about 35 minutes, or greater than or equal to about 40 minutes. The reaction time may be less than or equal to about 200 minutes, less than or equal to about 180 minutes, less than or equal to about 160 minutes, less than or equal to about 140 minutes, less than or equal to about 120 minutes, less than or equal to about 100 minutes, less than or equal to about 90 minutes, or less than or equal to about 80 minutes.

After completion of the reaction, the first semiconductor nanocrystal, a particle including the first semiconductor nanocrystal and the second semiconductor nanocrystal, or the obtained semiconductor nanoparticle may be recovered by pouring the resulting substance into an excess of a non-solvent to remove excess organic materials not coordinated on a surface of the semiconductor nanoparticle and subjecting the obtained mixture to centrifugation. For example, after completion of the reaction, when a non-solvent is added to a reaction product, semiconductor nanoparticles coordinated with the ligand compound may be separated. The non-solvent may be a polar solvent that is miscible with the solvent used in a core formation and/or shell formation reaction but is not capable of dispersing the prepared nanocrystal. The non-solvent may be determined according to the solvent used in the reaction, and may include, for example, acetone, ethanol, butanol, isopropanol, ethanediol, water, tetrahydrofuran (THF), dimethyl sulfoxide (DMSO), diethyl ether, formaldehyde, acetaldehyde, ethylene glycol, a solvent having a solubility parameter similar to those of the listed solvents, or a combination thereof. Separation may use centrifugation, precipitation, chromatography, or distillation. The separated nanocrystal may be added to a washing solvent and washed as needed. The washing solvent is not particularly limited and may be a solvent having a solubility parameter similar to that of the ligand, and examples thereof may include hexane, heptane, octane, chloroform, toluene, benzene, and the like.

The semiconductor nanoparticle may be non-dispersible or non-water-soluble with respect to water, the aforementioned non-solvent, or a combination thereof.

The semiconductor nanoparticles may be dispersed in the aforementioned organic solvent or liquid medium to form a first dispersion. Here, the dispersion (e.g., the first dispersion, a second dispersion, or a preliminary dispersion) may be a colloidal dispersion. The semiconductor nanoparticle of an embodiment may include, relative to an innate ligand (that is, bound to the semiconductor nanoparticle or a surface thereof during a synthesis process), a relatively long-chain ligand (e.g., a second ligand) and a short-chain ligand (e.g., a ligand of less than or equal to about C16 or less than or equal to about C8) (e.g., a first ligand). However, the present inventors have confirmed that there are limits to a maximum amount of the short-chain ligand and a minimum organic material amount of the semiconductor nanoparticle that can be implemented by synthesis. A semiconductor nanoparticle including an excessive amount of the short-chain ligand by synthesis or having a low organic material amount may fail to provide desired dispersion characteristics in a desired liquid medium (e.g., a relatively high-boiling hydrocarbon solvent such as cyclohexylbenzene). Here, the dispersion characteristics may be confirmed by a (mean) particle size (DLS particle size) determined by dynamic light scattering analysis or by UV-Vis absorption spectroscopy of the prepared dispersion. A dispersion including a semiconductor nanoparticle exhibiting a colloidal dispersion or a desired level of dispersibility may exhibit a relatively small DLS particle size (e.g., less than or equal to about 200 nm, less than or equal to about 100 nm, or less than or equal to about 50 nm), or may exhibit absorbance of less than or equal to about 10%, less than or equal to about 9%, less than or equal to about 8%, less than or equal to about 7%, less than or equal to about 6%, less than or equal to about 5%, less than or equal to about 4%, less than or equal to about 3%, less than or equal to about 2%, or less than or equal to about 1% of a first absorption peak intensity at a wavelength of a first absorption peak+100 nm in a UV-Vis absorption spectrum. The present inventors have surprisingly found that particles treated by the semiconductor nanoparticle treatment method described herein may exhibit desired dispersion characteristics in the liquid medium described herein even when including a relatively high level of the short-chain organic ligand or when a total organic material amount is relatively low.

In the semiconductor nanoparticle treatment method of an embodiment, a method of forming the first dispersion is not particularly limited, and may be obtained by adding the semiconductor nanoparticle or a preliminary dispersion including the same into a liquid medium and stirring. In an embodiment, the semiconductor nanoparticle recovered after synthesis may be dispersed in an additional solvent, for example, a C3 to C20 or C6 to C12 aliphatic hydrocarbon solvent (e.g., hexane, heptane, octane, nonane, decane, or the like) to form a preliminary dispersion, which may then be added to a predetermined liquid medium and stirred. In the treatment method of an embodiment, the semiconductor nanoparticle before surface treatment (e.g., in the first dispersion) may include an innate ligand (e.g., a short-chain ligand and a long-chain ligand). For details regarding the innate ligand, reference may be made to specific descriptions of organic ligands described herein. In the method of an embodiment, the liquid medium may have a relatively high boiling point, and accordingly, ligand exchange by addition of a ligand compound may also be performed at a relatively high temperature, for example, greater than or equal to about 120° C., greater than or equal to about 130° C., greater than or equal to about 150° C., greater than or equal to about 160° C., greater than or equal to about 170° C., greater than or equal to about 180° C., greater than or equal to about 190° C., greater than or equal to about 200° C., greater than or equal to about 210° C., greater than or equal to about 220° C., or greater than or equal to about 230° C. In this ligand exchange process, all of the additional solvent used for forming the preliminary dispersion may be removed.

In the treatment method of an embodiment, a metal halide may be added to the obtained first dispersion to precipitate the semiconductor nanoparticle.

The metal halide may include zinc, aluminum, indium, gallium, or a combination thereof. The metal halide may include ZnCl₂, AlCl₃, InCl₃, GaCl₃, ZnI₂, or a combination thereof.

Without wishing to be bound by any theory, addition of a metal halide (e.g., zinc chloride, aluminum chloride, zinc iodide, etc.) may cause desorption of surface ligands (e.g., innate ligands) of the semiconductor nanoparticles included in the first dispersion, and accordingly, the semiconductor nanoparticles in the first dispersion are considered to precipitate.

The metal halide may be added to the first dispersion in a solution state in a solvent miscible with the liquid medium. The solvent may include a ketone solvent such as acetone, an alcohol solvent such as ethanol, a C1 to C40 or C3 to C30 alkylphosphine solvent such as trioctylphosphine, or a combination thereof.

An amount of the metal halide may be controlled to induce substantial precipitation of the semiconductor nanoparticles in the first dispersion. In an embodiment, an amount of the metal halide (e.g., zinc chloride, etc.) added to the first dispersion may be an amount such that a concentration of the metal halide in the first dispersion is greater than or equal to about 0.0001 M (mole/L), greater than or equal to about 0.0005 M, greater than or equal to about 0.001 M, greater than or equal to about 0.005 M, greater than or equal to about 0.01 M, greater than or equal to about 0.015 M, greater than or equal to about 0.02 M, greater than or equal to about 0.025 M, greater than or equal to about 0.03 M, greater than or equal to about 0.04 M, greater than or equal to about 0.05 M, greater than or equal to about 0.06 M, greater than or equal to about 0.07 M, greater than or equal to about 0.08 M, greater than or equal to about 0.09 M, greater than or equal to about 0.1 M, greater than or equal to about 0.11 M, greater than or equal to about 0.12 M, greater than or equal to about 0.13 M, greater than or equal to about 0.14 M, greater than or equal to about 0.15 M, greater than or equal to about 0.16 M, greater than or equal to about 0.17 M, greater than or equal to about 0.18 M, greater than or equal to about 0.19 M, greater than or equal to about 0.2 M, greater than or equal to about 0.21 M, greater than or equal to about 0.22 M, greater than or equal to about 0.23 M, greater than or equal to about 0.24 M, greater than or equal to about 0.25 M, greater than or equal to about 0.26 M, greater than or equal to about 0.27 M, greater than or equal to about 0.28 M, greater than or equal to about 0.29 M, greater than or equal to about 0.3 M, greater than or equal to about 0.5 M, greater than or equal to about 1 M, greater than or equal to about 1.5 M, greater than or equal to about 2 M, greater than or equal to about 2.5 M, greater than or equal to about 3 M, greater than or equal to about 3.5 M, greater than or equal to about 4 M, greater than or equal to about 4.5 M, greater than or equal to about 5 M, greater than or equal to about 5.5 M, greater than or equal to about 6 M, greater than or equal to about 6.5 M, greater than or equal to about 7 M, greater than or equal to about 7.5 M, greater than or equal to about 8 M, greater than or equal to about 8.5 M, greater than or equal to about 9 M, greater than or equal to about 9.5 M, greater than or equal to about 10 M, greater than or equal to about 11 M, greater than or equal to about 12 M, greater than or equal to about 13 M, greater than or equal to about 14 M, greater than or equal to about 15 M, greater than or equal to about 16 M, greater than or equal to about 17 M, greater than or equal to about 18 M, greater than or equal to about 19 M, greater than or equal to about 20 M, greater than or equal to about 21 M, greater than or equal to about 22 M, greater than or equal to about 23 M, greater than or equal to about 24 M, greater than or equal to about 25 M, greater than or equal to about 26 M, greater than or equal to about 27 M, greater than or equal to about 28 M, greater than or equal to about 29 M, or greater than or equal to about 30 M.

The concentration of the metal halide in the first dispersion may be less than or equal to about 100 M, less than or equal to about 90 M, less than or equal to about 80 M, less than or equal to about 70 M, less than or equal to about 60 M, less than or equal to about 50 M, less than or equal to about 40 M, less than or equal to about 30 M, or less than or equal to about 20 M.

Addition of the metal halide may precipitate greater than or equal to about 10%, greater than or equal to about 20%, greater than or equal to about 30%, greater than or equal to about 40%, greater than or equal to about 50%, greater than or equal to about 60%, greater than or equal to about 70%, greater than or equal to about 80%, greater than or equal to about 81%, greater than or equal to about 82%, greater than or equal to about 83%, greater than or equal to about 84%, greater than or equal to about 85%, greater than or equal to about 86%, greater than or equal to about 87%, greater than or equal to about 88%, greater than or equal to about 89%, greater than or equal to about 90%, greater than or equal to about 91%, greater than or equal to about 92%, greater than or equal to about 93%, greater than or equal to about 94%, greater than or equal to about 95%, greater than or equal to about 96%, greater than or equal to about 97%, greater than or equal to about 98%, greater than or equal to about 99%, or greater than or equal to about 100% of the semiconductor nanoparticles in the first dispersion.

In the treating method of an embodiment, a ligand compound is added to the first dispersion including the precipitated semiconductor nanoparticles, and stirred and mixed at a predetermined temperature. The ligand compound may include a functional group configured to interact with a surface of the semiconductor nanoparticle (e.g., a carboxyl group, an amine group, or a combination thereof). By such mixing, the semiconductor nanoparticles precipitated in the first dispersion may be converted again into, for example, a colloidally dispersed state in the liquid medium (e.g., substantially transparent as observed with the naked eye), thereby forming a second dispersion. The stirring or mixing may be performed at a temperature of greater than or equal to about 120° C., greater than or equal to about 130° C., greater than or equal to about 140° C., greater than or equal to about 150° C., greater than or equal to about 160° C., greater than or equal to about 170° C., greater than or equal to about 180° C., greater than or equal to about 190° C., or greater than or equal to about 200° C. The stirring or mixing temperature may be performed at a temperature of less than or equal to about 250° C., or less than or equal to about 240° C.

An amount of the ligand compound to be added may be, based on the metal halide, greater than or equal to about 0.01 mole %, greater than or equal to about 0.05 mole %, greater than or equal to about 0.1 mole %, greater than or equal to about 0.5 mole %, greater than or equal to about 1 mole %, greater than or equal to about 2 mole %, greater than or equal to about 3 mole %, greater than or equal to about 4 mole %, greater than or equal to about 5 mole %, greater than or equal to about 6 mole %, greater than or equal to about 7 mole %, greater than or equal to about 8 mole %, greater than or equal to about 9 mole %, greater than or equal to about 10 mole %, greater than or equal to about 11 mole %, greater than or equal to about 12 mole %, greater than or equal to about 13 mole %, greater than or equal to about 14 mole %, greater than or equal to about 15 mole %, greater than or equal to about 16 mole %, greater than or equal to about 17 mole %, greater than or equal to about 18 mole %, greater than or equal to about 19 mole %, greater than or equal to about 20 mole %, greater than or equal to about 21 mole %, greater than or equal to about 22 mole %, greater than or equal to about 23 mole %, greater than or equal to about 24 mole %, greater than or equal to about 25 mole %, greater than or equal to about 26 mole %, greater than or equal to about 27 mole %, greater than or equal to about 28 mole %, greater than or equal to about 29 mole %, greater than or equal to about 30 mole %, greater than or equal to about 31 mole %, greater than or equal to about 32 mole %, greater than or equal to about 33 mole %, greater than or equal to about 34 mole %, greater than or equal to about 35 mole %, greater than or equal to about 36 mole %, greater than or equal to about 37 mole %, greater than or equal to about 38 mole %, greater than or equal to about 39 mole %, greater than or equal to about 40 mole %, greater than or equal to about 41 mole %, greater than or equal to about 42 mole %, greater than or equal to about 43 mole %, greater than or equal to about 44 mole %, greater than or equal to about 45 mole %, greater than or equal to about 46 mole %, greater than or equal to about 47 mole %, greater than or equal to about 48 mole %, greater than or equal to about 49 mole %, greater than or equal to about 50 mole %, greater than or equal to about 75 mole %, greater than or equal to about 100 mole %, greater than or equal to about 110 mole %, greater than or equal to about 120 mole %, greater than or equal to about 130 mole %, greater than or equal to about 140 mole %, greater than or equal to about 150 mole %, greater than or equal to about 160 mole %, greater than or equal to about 170 mole %, greater than or equal to about 180 mole %, greater than or equal to about 190 mole %, or greater than or equal to about 200 mole %. The amount of the ligand compound may be less than or equal to about 5000 mole %, less than or equal to about 3000 mole %, less than or equal to about 1000 mole %, less than or equal to about 900 mole %, less than or equal to about 800 mole %, less than or equal to about 700 mole %, less than or equal to about 600 mole %, less than or equal to about 500 mole %, less than or equal to about 400 mole %, less than or equal to about 300 mole %, less than or equal to about 200 mole %, less than or equal to about 100 mole %, less than or equal to about 90 mole %, less than or equal to about 80 mole %, less than or equal to about 70 mole %, less than or equal to about 60 mole %, less than or equal to about 50 mole %, less than or equal to about 40 mole %, less than or equal to about 30 mole %, or less than or equal to about 20 mole %, based on the metal halide.

Without wishing to be bound by any theory, such addition of the ligand compound and stirring/mixing may provide coordination or surface binding of the ligand compound to the semiconductor nanoparticle (e.g., at ligand desorption sites caused by zinc chloride), and accordingly, the semiconductor nanoparticles surface-exchanged with the ligand compound are considered to recover dispersibility in the liquid medium, thereby forming a second dispersion. Therefore, the second dispersion comprises semiconductor nanoparticles surface-treated with the ligand compound. An embodiment is directed to such surface-treated semiconductor nanoparticles.

In an embodiment, the ligand compound may be a compound including a first organic ligand, and accordingly, the surface-treated semiconductor nanoparticle (hereinafter, may be abbreviated as a semiconductor nanoparticle) may include the first organic ligand on a surface thereof. The surface-treated semiconductor nanoparticle may further include or may not include a second organic ligand different from the first organic ligand. In an embodiment, the surface-treated semiconductor nanoparticle may include a ligand system including the first organic ligand and, optionally, the second organic ligand.

The ligand system may be bound or disposed on a surface of the semiconductor nanoparticle (or a semiconductor nanocrystal shell). The semiconductor nanoparticle or the ligand system may further include a halogen (e.g., a halide). A total sum of numbers of carbons in organic ligand molecules (e.g., the first and second organic ligands) present in the ligand system may be greater than or equal to about 20, greater than or equal to about 21, greater than or equal to about 22, greater than or equal to about 23, greater than or equal to about 24, greater than or equal to about 25, greater than or equal to about 26, greater than or equal to about 27, greater than or equal to about 28, or greater than or equal to about 29. The total sum of the numbers of carbons may be less than or equal to about 40, less than or equal to about 38, less than or equal to about 36, less than or equal to about 35, less than or equal to about 34, less than or equal to about 33, less than or equal to about 32, less than or equal to about 31, less than or equal to about 30, less than or equal to about 29, less than or equal to about 28, or less than or equal to about 27.

The first organic ligand may be derived from the ligand compound. In an embodiment, the ligand compound may include a first carboxylic acid compound (for example, represented by Chemical formula 2). The ligand compound may include an amine compound represented by R(CR₂)ₙNH₂. Definitions of R and n are the same as those in Chemical formula 2. The ligand compound may include an organic ligand included in a synthesis process (e.g., an innate ligand such as a short-chain/long-chain ligand), or may include a ligand different from the innate ligand. The treatment method of an embodiment may involve detachment of at least a portion of the innate ligand (e.g., a short-chain ligand and a long-chain ligand) and subsequent reattachment of the ligand compound. Accordingly, (for example, in both cases where the ligand compound is the same as or different from the innate organic ligand) a surface state of the semiconductor nanoparticle may be different from a synthesized ligand system (e.g., in terms of a type or an amount of a ligand), and the surface-treated semiconductor nanoparticle may exhibit dispersion characteristics different from those of the semiconductor nanoparticle before surface treatment.

The first organic ligand may include a carboxylate moiety, an amine moiety, or a combination thereof. In an embodiment, the first organic ligand may include a carboxylate moiety. The second organic ligand may include a carboxylate moiety, an amine moiety, or a combination thereof. In an embodiment, the second organic ligand may include a carboxylate moiety. The first organic ligand may have a number of carbons of greater than or equal to about 2, or greater than or equal to about 5 and less than or equal to about 16, or less than or equal to about 14. The second organic ligand may have a number of carbons of greater than or equal to about 14, or greater than or equal to about 17 and less than or equal to about 40, or less than or equal to about 24. The second organic ligand may have a molecular weight greater than that of the first organic ligand.

The first organic ligand may have a molecular weight of greater than or equal to about 90 g/mol, greater than or equal to about 100 g/mol, greater than or equal to about 105 g/mol, greater than or equal to about 110 g/mol, greater than or equal to about 115 g/mol, greater than or equal to about 120 g/mol, greater than or equal to about 125 g/mol, greater than or equal to about 130 g/mol, greater than or equal to about 140 g/mol, greater than or equal to about 150 g/mol, greater than or equal to about 160 g/mol, greater than or equal to about 170 g/mol, greater than or equal to about 180 g/mol, greater than or equal to about 190 g/mol, or greater than or equal to about 200 g/mol. The first organic ligand may have a molecular weight of less than or equal to about 257 g/mol, less than or equal to about 230 g/mol, less than or equal to about 225 g/mol, less than or equal to about 220 g/mol, less than or equal to about 215 g/mol, less than or equal to about 210 g/mol, less than or equal to about 200 g/mol, less than or equal to about 190 g/mol, less than or equal to about 180 g/mol, less than or equal to about 170 g/mol, less than or equal to about 160 g/mol, less than or equal to about 155 g/mol, less than or equal to about 150 g/mol, less than or equal to about 145 g/mol, less than or equal to about 140 g/mol, or less than or equal to about 130 g/mol.

The first organic ligand may include a (aliphatic, aromatic, or alicyclic) hydrocarbon group. The hydrocarbon group of the first organic ligand may include a substituted or unsubstituted C6 to C16 aromatic hydrocarbon group, or a substituted or unsubstituted, C2 to C16, C2 to C14, C3 to C12, C4 to C10, C5 to C9, C4 to C8, or C6 to C7 linear or branched aliphatic hydrocarbon group (e.g., an alkyl group, an alkenyl group, or an alkynyl group). The first organic ligand may include a branched alkyl group.

In an embodiment, the ligand compound may include a carboxylic acid compound, and the first organic ligand may include a propanoate moiety, an isopropanoate moiety, a butyrate moiety, a butyrate moiety having one or more C1 to C3 alkyl groups (e.g., an ester of methylbutanoic acid or an ester of ethylbutanoic acid), a valerate (or pentanoic acid ester) moiety, a valerate moiety substituted with one or more C1 to C4 alkyl groups (e.g., an ester of methylvaleric acid or an ester of propylpentanoic acid), a hexanoate moiety, a hexanoate moiety substituted with one or more C1 to C5 alkyl groups (e.g., an ester moiety of ethylhexanoic acid), an octanoate moiety, an octanoate moiety substituted with a C1 to C6 alkyl group (e.g., an ester of butyloctanoic acid), or a combination thereof.

The first organic ligand may include a carboxylate moiety (e.g., a carboxylate anion) represented by the following Chemical formula 1-1 or an amine moiety represented by the following Chemical formula 1-2, and a total number of carbons included in the first organic ligand may be 3 to 15, or 4 to 13, or 5 to 11, or 6 to 10:

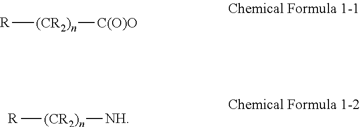

In the above formulae, each R may be the same as or different and may each independently be hydrogen or a C1 to C6 or C2-C4 or C3-C5 alkyl group (e.g., a methyl group, an ethyl group, a propyl group, a butyl group, a pentyl group, or a hexyl group), and n is an integer of 1 to 14, or 2 to 12, or 3 to 10, or 4 to 8.

The second organic ligand may have a molecular weight greater than that of the first organic ligand or may have a greater number of carbons than the first organic ligand. A difference between a molecular weight of the second organic ligand and a molecular weight of the first organic ligand may be greater than or equal to about 50 g/mol, greater than or equal to about 75 g/mol, greater than or equal to about 80 g/mol, greater than or equal to about 90 g/mol, greater than or equal to about 100 g/mol, greater than or equal to about 120 g/mol, greater than or equal to about 130 g/mol, or greater than or equal to about 150 g/mol. The difference between the molecular weight of the second organic ligand and the molecular weight of the first organic ligand may be less than or equal to about 240 g/mol, less than or equal to about 220 g/mol, less than or equal to about 200 g/mol, less than or equal to about 180 g/mol, less than or equal to about 160 g/mol, less than or equal to about 150 g/mol, less than or equal to about 140 g/mol, less than or equal to about 130 g/mol, less than or equal to about 120 g/mol, less than or equal to about 100 g/mol, or less than or equal to about 90 g/mol.

The second organic ligand may have a molecular weight of greater than about 200 g/mol, greater than or equal to about 210 g/mol, greater than or equal to about 215 g/mol, greater than or equal to about 220 g/mol, greater than or equal to about 225 g/mol, greater than or equal to about 230 g/mol, greater than or equal to about 235 g/mol, greater than or equal to about 240 g/mol, greater than or equal to about 245 g/mol, greater than or equal to about 250 g/mol, greater than or equal to about 255 g/mol, greater than or equal to about 260 g/mol, greater than or equal to about 265 g/mol, greater than or equal to about 270 g/mol, or greater than or equal to about 280 g/mol. The second organic ligand may have a molecular weight of less than or equal to about 500 g/mol, less than or equal to about 450 g/mol, less than or equal to about 440 g/mol, less than or equal to about 430 g/mol, less than or equal to about 420 g/mol, less than or equal to about 410 g/mol, less than or equal to about 400 g/mol, less than or equal to about 390 g/mol, less than or equal to about 380 g/mol, less than or equal to about 370 g/mol, less than or equal to about 360 g/mol, less than or equal to about 350 g/mol, less than or equal to about 340 g/mol, or less than or equal to about 250 g/mol.

The second organic ligand may include a linear or branched aliphatic hydrocarbon group of C12 to C25, C13 to C23, C14 to C22, C16 to C21, C17 to C20, or C18 to C19 (e.g., an alkyl group, an alkenyl group, or an alkynyl group). The second organic ligand may include a tetradecyl group, a tetradecenyl group, a pentadecyl group, a pentadecenyl group, a hexadecyl group, a hexadecenyl group, a heptadecyl group, a heptadecenyl group, an octadecyl group, an octadecenyl group, an octadecadienyl group, an octadecatrienyl group, or a combination thereof.

The second organic ligand may include, for example, one or more carbon-carbon double bonds, or two or more carbon-carbon double bonds, in the aliphatic hydrocarbon group. The second organic ligand may include an oleylamine moiety, an ester moiety of linolenic acid, an ester moiety of linoleic acid, an ester moiety of oleic acid, an ester moiety of elaidic acid, an ester moiety of stearic acid, an ester moiety of palmitic acid, an ester moiety of myristic acid, or a combination thereof. In an embodiment, the second organic ligand may comprise a C16 to C30 carboxylic acid compound including a carbon-carbon double bond in a carbon chain.

In an embodiment, the first organic ligand may not include a double bond and may include, for example, a branched alkyl group, and the second organic ligand may include a linear alkenyl group including a double bond.

In an embodiment, the surface-treated semiconductor nanoparticle may include the first organic ligand and the second organic ligand together, and may exhibit, in gas chromatography (GC) analysis (e.g., in a chromatogram obtained by gas chromatography analysis), a first peak assigned to the first organic ligand and a second peak assigned to the second organic ligand. In the case of GC-MS analysis, detection sensitivity may vary depending on a molecular weight (MW) of a ligand. In order to correct a difference in detection sensitivity according to the molecular weight (MW) of the ligand, an area of each peak may be divided by the MW corresponding to each ligand, and a relative ratio may be derived based on the obtained values. In other words, a GC area-corrected value is a value obtained by dividing a GC area of a corresponding ligand by the MW of the corresponding ligand.

Accordingly, in an embodiment, a value obtained by dividing a first peak area of a first organic ligand by a molecular weight of the first organic ligand is referred to as a first peak area correction value, and a value obtained by dividing a second peak area of a second organic ligand by a molecular weight of the second organic ligand is referred to as a second peak area correction value.

The surface-treated semiconductor nanoparticle may have a second organic ligand fraction calculated by the following equation of less than or equal to about 80%, less than or equal to about 75%, less than or equal to about 69%, less than or equal to about 65%, or less than or equal to about 61%:

$$second organic ligand fraction = [ \text{} second peak area correction value / ( second peak area correction value + first peak area correction value ) ] \times 100 ( \% )$$

The second organic ligand fraction may be less than or equal to about 60%, less than or equal to about 59%, less than or equal to about 58%, less than or equal to about 57%, less than or equal to about 56%, less than or equal to about 55%, less than or equal to about 54%, less than or equal to about 53%, less than or equal to about 52%, less than or equal to about 51%, less than or equal to about 50%, less than or equal to about 49%, less than or equal to about 48%, less than or equal to about 47%, less than or equal to about 46%, less than or equal to about 45%, less than or equal to about 44%, less than or equal to about 43%, less than or equal to about 42%, less than or equal to about 41%, less than or equal to about 40%, less than or equal to about 39%, less than or equal to about 38%, less than or equal to about 37%, less than or equal to about 36%, less than or equal to about 35%, less than or equal to about 34%, less than or equal to about 33%, less than or equal to about 32%, less than or equal to about 31%, less than or equal to about 30%, less than or equal to about 29%, less than or equal to about 28%, less than or equal to about 27%, less than or equal to about 26%, less than or equal to about 25%, less than or equal to about 24%, less than or equal to about 23%, less than or equal to about 22%, less than or equal to about 21%, less than or equal to about 20%, less than or equal to about 19%, less than or equal to about 18%, less than or equal to about 17%, less than or equal to about 16%, less than or equal to about 15%, less than or equal to about 14%, less than or equal to about 13%, less than or equal to about 12%, less than or equal to about 11%, less than or equal to about 10%, less than or equal to about 9%, less than or equal to about 8%, less than or equal to about 7%, less than or equal to about 6%, less than or equal to about 5%, less than or equal to about 4%, less than or equal to about 3%, less than or equal to about 2%, or less than or equal to about 1%.

In the surface-treated semiconductor nanoparticle, the second organic ligand fraction may be greater than or equal to about 0%, greater than or equal to about 0.01%, greater than or equal to about 1%, greater than or equal to about 3%, greater than or equal to about 10%, greater than or equal to about 15%, greater than or equal to about 20%, greater than or equal to about 25%, or greater than or equal to about 30%. In an embodiment, the surface-treated semiconductor nanoparticle may not include the second peak substantially.

A retention time (or acquisition time) of the second peak may be longer than a retention time of the first peak. A ratio of the retention time of the first peak (peak elution time of the first organic ligand) to the retention time of the second peak (peak elution time of the second organic ligand) may be greater than or equal to about 0.1, greater than or equal to about 0.2, greater than or equal to about 0.3, greater than or equal to about 0.4, greater than or equal to about 0.5, greater than or equal to about 0.6, or greater than or equal to about 0.7. The ratio between the retention times may be less than or equal to about 1, less than or equal to about 0.9, less than or equal to about 0.8, or less than or equal to about 0.7.

A difference in retention time between the second peak and the first peak may be greater than or equal to about 2 minutes, greater than or equal to about 3 minutes, greater than or equal to about 4 minutes, greater than or equal to about 5 minutes, greater than or equal to about 6 minutes, greater than or equal to about 8 minutes, greater than or equal to about 9 minutes, or greater than or equal to about 10 minutes. The difference in retention time between the second peak and the first peak may be less than or equal to about 15 minutes, less than or equal to about 13 minutes, less than or equal to about 12 minutes, less than or equal to about 11 minutes, less than or equal to about 10 minutes, less than or equal to about 9 minutes, less than or equal to about 7 minutes, or less than or equal to about 2 minutes.

A gas chromatography (GC) is an analytical technique that may be used to separate, identify, and quantify individual chemical components in complex mixtures. In the GC, a gas carries a sample through the GC instrument. In an embodiment, a carrier gas or a mobile phase is not particularly limited and may be a high-purity helium, hydrogen, or nitrogen. In an embodiment, the gas chromatography analysis apparatus may include an injector (e.g., split/splitless (SSL) injector), a column (e.g., a wall-coated open tubular (WCOT) capillary column including a thin layer of dimethylpolysiloxane stationary phase), and a detector (e.g., flame ionization detector, FID, or mass spectrometry, MS), but is not limited thereto. In an embodiment, the GC column may be a capillary column and may be a fused silica capillary tube including a polymer outer coating. In the chromatogram obtained by GC, the x-axis represents retention time (typically in minutes) and the y-axis represents detector response. In an embodiment, the GC apparatus may be pyrolysis-gas chromatography-mass spectrometry (py-GC/MS) apparatus. In the GC, the temperature of the pyrolyzer may be 400° C. to 600° C. or 450° C. to 550° C. The GC apparatus may include a capillary column. The capillary column may include a stationary phase of polysiloxane (e.g., dimethylpolysiloxane, 5% to 65% diphenyldimethylpolysiloxane, polyethylene glycol, etc.), and the polarity may be appropriately selected.

The flow rate of the mobile phase (gas) may be appropriately selected and may be in the range of 0.5 milliliter per minute (mL/min) to 10 mL/min, or 1 mL/min to 5 mL/min, or 1.5 mL/min to 3 mL/min. The inlet temperature of the GC apparatus may be appropriately selected and may be in the range of 100° C. to 400° C., 150° C. to 300° C., or 200° C. to 250° C. The GC oven temperature may be appropriately controlled. The analyzer may be a quadrupole (range: 10~550 mass-to-charge ratio (m/z)).

In an embodiment, the (surface-treated) semiconductor nanoparticle, as confirmed by thermogravimetric analysis, may exhibit a relatively reduced organic content while still exhibiting a desired level of dispersibility in an organic solvent (for example, in an aliphatic hydrocarbon solvent such as octane). In an embodiment, a weight decreased in a range of greater than or equal to about 200° C. to less than or equal to about 550° C., based on a total weight of the semiconductor nanoparticle, may be less than or equal to about 13 weight %, less than or equal to about 12 weight %, less than or equal to about 11.5 weight %, less than or equal to about 11 weight %, less than or equal to about 10.5 weight %, less than or equal to about 10 weight %, less than or equal to about 9.5 weight %, less than or equal to about 9 weight %, less than or equal to about 8.5 weight %, less than or equal to about 8 weight %, less than or equal to about 7.5 weight %, less than or equal to about 7 weight %, less than or equal to about 6.5 weight %, less than or equal to about 6 weight %, less than or equal to about 5.5 weight %, less than or equal to about 5 weight %, less than or equal to about 4.5 weight %, or less than or equal to about 4 weight %. The semiconductor nanoparticle, in thermogravimetric analysis, may have a weight decreased in a range of greater than or equal to about 200° C. to less than or equal to about 550° C. of greater than or equal to about 1 weight %, greater than or equal to about 3 weight %, greater than or equal to about 5 weight %, or greater than or equal to about 7 weight %, based on the total weight of the semiconductor nanoparticle.

The (surface-treated) semiconductor nanoparticle, in thermogravimetric analysis, may have a residue content at greater than or equal to about 550° C., based on the total weight of the semiconductor nanoparticle, of greater than or equal to about 80 weight %, greater than or equal to about 83 weight %, greater than or equal to about 87 weight %, greater than or equal to about 88 weight %, greater than or equal to about 90 weight %, greater than or equal to about 91 weight %, greater than or equal to about 92 weight %, greater than or equal to about 93 weight %, greater than or equal to about 95 weight %, greater than or equal to about 96 weight %, greater than or equal to about 97 weight %, greater than or equal to about 98 weight %, or greater than or equal to about 99 weight %. The semiconductor nanoparticle, in thermogravimetric analysis, may have a residue content at greater than or equal to about 550° C., based on the total weight of the semiconductor nanoparticle, of less than about 100 weight %, less than or equal to about 99 weight %, less than or equal to about 97 weight %, less than or equal to about 92 weight %, or less than or equal to about 90 weight %.

The surface-treated semiconductor nanoparticle may exhibit solvent dispersion characteristics different from those of a semiconductor nanoparticle before surface treatment. In an embodiment, improved dispersibility may be exhibited in an organic solvent (for example, a high-boiling-point organic solvent for an inkjet printing composition).

The semiconductor nanoparticle may further include a halogen. The halogen may be fluorine, chlorine, bromine, iodine, or a combination thereof. In an embodiment, the halogen may be chlorine.

In the semiconductor nanoparticle, a mole ratio of halogen to zinc may be greater than or equal to about 0.005:1, greater than or equal to about 0.01:1, greater than or equal to about 0.02:1, greater than or equal to about 0.03:1, greater than or equal to about 0.04:1, greater than or equal to about 0.05:1, greater than or equal to about 0.08:1, greater than or equal to about 0.1:1, greater than or equal to about 0.15:1, or greater than or equal to about 0.2:1. In the semiconductor nanoparticle, the mole ratio of halogen to zinc may be less than or equal to about 50:1, less than or equal to about 10:1, less than or equal to about 9:1, less than or equal to about 8:1, less than or equal to about 5:1, less than or equal to about 1:1, less than or equal to about 0.9:1, less than or equal to about 0.7:1, less than or equal to about 0.6:1, less than or equal to about 0.4:1, less than or equal to about 0.2:1, less than or equal to about 0.12:1, less than or equal to about 0.09:1, less than or equal to about 0.07:1, less than or equal to about 0.06:1, or less than or equal to about 0.05:1.

In the semiconductor nanoparticle, a mole ratio of halogen to selenium may be greater than or equal to about 0.005:1, greater than or equal to about 0.01:1, greater than or equal to about 0.02:1, greater than or equal to about 0.03:1, greater than or equal to about 0.04:1, greater than or equal to about 0.05:1, greater than or equal to about 0.08:1, greater than or equal to about 0.1:1, greater than or equal to about 0.15:1, or greater than or equal to about 0.2:1. In the semiconductor nanoparticle, the mole ratio of halogen to selenium may be less than or equal to about 100:1, less than or equal to about 50:1, less than or equal to about 10:1, less than or equal to about 9:1, less than or equal to about 8:1, less than or equal to about 5:1, less than or equal to about 1:1, less than or equal to about 0.9:1, less than or equal to about 0.7:1, less than or equal to about 0.6:1, less than or equal to about 0.4:1, less than or equal to about 0.2:1, less than or equal to about 0.12:1, less than or equal to about 0.09:1, less than or equal to about 0.07:1, less than or equal to about 0.06:1, or less than or equal to about 0.05:1.

In the semiconductor nanoparticle, a mole ratio of carbon to zinc may be greater than or equal to about 0.005:1, greater than or equal to about 0.01:1, greater than or equal to about 0.05:1, greater than or equal to about 0.1:1, greater than or equal to about 0.15:1, greater than or equal to about 0.2:1, greater than or equal to about 0.25:1, greater than or equal to about 0.3:1, greater than or equal to about 0.35:1, greater than or equal to about 0.4:1, or greater than or equal to about 0.45:1. In the semiconductor nanoparticle, the mole ratio of carbon to zinc may be less than or equal to about 1:1, less than or equal to about 0.9:1, less than or equal to about 0.7:1, or less than or equal to about 0.5:1.

In the semiconductor nanoparticle, a mole ratio of sulfur to selenium may be greater than or equal to about 0.4:1, greater than or equal to about 0.5:1, greater than or equal to about 0.6:1, greater than or equal to about 0.7:1, greater than or equal to about 0.8:1, or greater than or equal to about 0.9:1. In the semiconductor nanoparticle, the mole ratio of sulfur to selenium may be less than or equal to about 1:1, less than or equal to about 0.95:1, less than or equal to about 0.85:1, less than or equal to about 0.75:1, less than or equal to about 0.65:1, less than or equal to about 0.55:1, or less than or equal to about 0.45:1.

A mole amount of an element or a mole ratio among elements (for example, included in the semiconductor nanoparticle or the light emitting layer) as described herein may be determined through, e.g., with, an appropriate analysis tool (e.g., an inductively coupled plasma atomic emission spectroscopy (ICP-AES), an X-ray photoelectron spectroscopy (XPS), an ion chromatography, a transmission electron microscopy energy-dispersive X-ray spectroscopy (TEM-EDX), a scanning electron microscopy energy-dispersive X-ray spectroscopy (SEM-EDX), a X-ray fluorescence (XRF), or a combination thereof).

The recovery may include adding a precipitation solvent to the second dispersion. The precipitation solvent may be a non-solvent used in a synthesis process of the semiconductor nanoparticle. In an embodiment, the precipitation solvent may include acetone, ethanol, butanol, isopropanol, ethanediol, water, tetrahydrofuran (THF), dimethyl sulfoxide (DMSO), diethyl ether, formaldehyde, acetaldehyde, ethylene glycol, a solvent having a solubility parameter similar to those of the listed solvents, or a combination thereof.

In an embodiment, the surface-treated semiconductor nanoparticle may exhibit improved dispersibility with respect to a liquid medium (or a liquid vehicle). The surface-treated semiconductor nanoparticle may form a colloidal dispersion in the liquid medium without assistance of another co-solvent (for example, an additional solvent).

Accordingly, an embodiment relates to an ink composition including a liquid medium (for example, a liquid vehicle) and a (surface-treated) semiconductor nanoparticle dispersed in the liquid medium. Details regarding the liquid medium (liquid vehicle) and the (surface-treated) semiconductor nanoparticle are as described herein.

In an embodiment, an amount of the semiconductor nanoparticle in the ink composition may be appropriately selected. In an embodiment, the amount of the semiconductor nanoparticle in the ink composition, based on a total weight of the composition, may be greater than or equal to about 1 weight %, greater than or equal to about 5 weight %, greater than or equal to about 10 weight %, greater than or equal to about 15 weight %, greater than or equal to about 20 weight %, greater than or equal to about 25 weight %, greater than or equal to about 30 weight %, greater than or equal to about 35 weight %, or greater than or equal to about 40 weight %. In an embodiment, the amount of the semiconductor nanoparticle in the ink composition, based on the total weight of the composition, may be less than or equal to about 99 weight %, less than or equal to about 95 weight %, less than or equal to about 90 weight %, less than or equal to about 85 weight %, less than or equal to about 80 weight %, less than or equal to about 75 weight %, less than or equal to about 70 weight %, less than or equal to about 65 weight %, or less than or equal to about 60 weight %.

In an embodiment, the surface-treated semiconductor nanoparticle or an ink composition including the same, as measured by dynamic light scattering analysis, may exhibit a DLS particle diameter of less than about 450 nm, less than or equal to about 400 nm, or less than or equal to about 300 nm. The DLS particle diameter may be less than or equal to about 200 nm, less than or equal to about 100 nm, less than or equal to about 80 nm, less than or equal to about 60 nm, less than or equal to about 50 nm, less than or equal to about 40 nm, less than or equal to about 30 nm, or less than or equal to about 20 nm. The DLS particle diameter may be greater than or equal to about 5 nm, greater than or equal to about 7 nm, greater than or equal to about 10 nm, greater than or equal to about 15 nm, or greater than or equal to about 20 nm.

The semiconductor nanoparticle, by having the features described herein, may contribute to enabling the composition to exhibit an appropriate viscosity when included in the ink composition. The viscosity may be in a range of greater than or equal to about 0.5 centipoise (cPs) to less than or equal to about 30 cPs, greater than or equal to about 1 cPs to less than or equal to about 15 cPs, greater than or equal to about 1.5 cPs to less than or equal to about 10 cPs, greater than or equal to about 2 cPs to less than or equal to about 8 cPs, greater than or equal to about 2.5 cPs to less than or equal to about 5 cPs, greater than or equal to about 2.8 cPs to less than or equal to about 3.5 cPs, or a combination thereof.

The ink composition of an embodiment may exhibit surface tension or wettability with respect to a common layer included in an electroluminescent device described below, for example, a hole auxiliary layer or an electron auxiliary layer. The surface tension may be in a range of greater than or equal to about 10 millinewtons per meter (mN/m) to less than or equal to about 100 mN/m, greater than or equal to about 15 mN/m to less than or equal to about 80 mN/m, greater than or equal to about 20 mN/m to less than or equal to about 50 mN/m, greater than or equal to about 25 mN/m to less than or equal to about 45 mN/m, greater than or equal to about 30 mN/m to less than or equal to about 40 mN/m, greater than or equal to about 33 mN/m to less than or equal to about 38 mN/m, or a combination thereof.

In an embodiment, the surface-treated semiconductor nanoparticle may be included in an emission layer in an electronic device, for example, an electroluminescent device, and may contribute to improvement of device lifetime and the like. Accordingly, an embodiment relates to an electroluminescent device including the semiconductor nanoparticle.

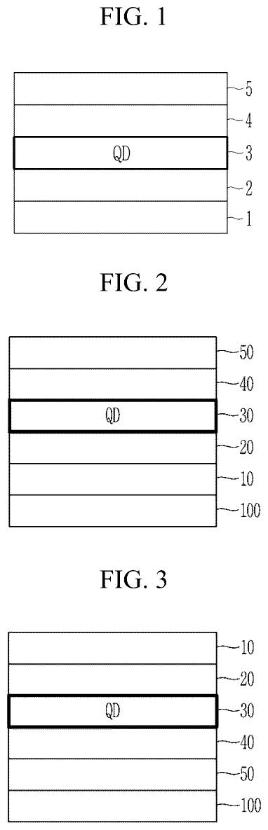

In an embodiment, an electroluminescent device comprises a first electrode 1 and a second electrode 5 that are spaced apart (e.g., facing each other); and an emission layer 3 disposed between the first electrode and the second electrode (see FIG. 1). The emission layer comprises the semiconductor nanoparticle. The emission layer or the semiconductor nanoparticle may not include cadmium. The first electrode may include an anode, and the second electrode may include a cathode. Alternatively, the first electrode may include a cathode and the second electrode may include an anode. The electroluminescent device may further include a hole auxiliary layer 2 between the emission layer and the first electrode. The electroluminescent device may further include an electron auxiliary layer 4 between the emission layer and the second electrode.

In the electroluminescent device, the first electrode 10 or the second electrode 20 may be disposed on a (transparent) substrate 100. The transparent substrate may be a light extraction surface (see FIGS. 2 and 3).

Referring to FIGS. 2 and 3, an emission layer 30 may be disposed between a first electrode (e.g., an anode) 10 and a second electrode (e.g., a cathode) 50. The second electrode or cathode 50 may include an electron injection conductor. The first electrode or anode 10 may include a hole injection conductor. A work function of the electron/hole injection conductor included in the second electrode and the first electrode may be appropriately adjusted and is not particularly limited. For example, the second electrode may have a small work function and the first electrode may have a relatively large work function, or vice versa.

The electron/hole injection conductor may include, but is not limited to, a metal-containing material (e.g., a metal, a metal compound, an alloy, or a combination thereof) such as aluminum, magnesium, tungsten, nickel, cobalt, platinum, palladium, calcium, or LiF; a metal oxide such as gallium indium oxide or indium tin oxide (ITO); or a conductive polymer such as polyethylene dioxythiophene (e.g., having a relatively high work function).

At least one of the first electrode and the second electrode may be a light-transmitting electrode or a transparent electrode. In an embodiment, both the first electrode and the second electrode may be light-transmitting electrodes. The electrode(s) may be patterned. The first electrode and/or the second electrode may be disposed on a (e.g., insulating) substrate 100. The substrate 100 may be optically transparent (e.g., having a light transmittance of greater than or equal to about 50%, greater than or equal to about 60%, greater than or equal to about 70%, greater than or equal to about 80%, greater than or equal to about 85%, or greater than or equal to about 90%, and for example, less than or equal to about 99% or less than or equal to about 95%). The substrate may further include a region for a blue pixel, a region for a red pixel, a region for a green pixel, or a combination thereof. In each of the regions of the substrate, a thin film transistor may be disposed, and one of a source electrode and a drain electrode of the thin film transistor may be electrically connected to the first electrode or the second electrode.

The light-transmitting electrode may be disposed on a (e.g., insulating) transparent substrate. The substrate may be rigid or flexible. The substrate may be plastic, glass, or metal.

The light-transmitting electrode may have a light transmittance of greater than or equal to about 50%, greater than or equal to about 60%, greater than or equal to about 70%, greater than or equal to about 80%, or greater than or equal to about 90%, for example, in a range of about 80% to about 100%, about 85% to about 95%, or a combination thereof.

The light-transmitting electrode may include, for example, a transparent conductor such as indium tin oxide (ITO), indium zinc oxide (IZO), gallium indium tin oxide, zinc indium tin oxide, titanium nitride, polyaniline, or LiF/Mg:Ag, or a single-layer or a plurality of metal thin films having a small thickness, but is not limited thereto. The first electrode, the second electrode, or a combination thereof may include aluminum (Al), a lithium-aluminum (Li:Al) alloy, a magnesium-silver alloy (Mg:Ag), lithium fluoride-aluminum (LiF:Al), or the like. In the case of an alloy electrode, a ratio between respective materials may be appropriately adjusted, and may be, for example, in a range of greater than or equal to about 1:0.1 to less than or equal to about 1:10, greater than or equal to about 1:0.2 to less than or equal to about 1:5, greater than or equal to about 1:0.3 to less than or equal to about 1:3, or a combination thereof.

In an embodiment, the first electrode or the second electrode may be a multilayer electrode. In an embodiment, the first electrode (or an anode) may be a multilayer electrode including electrode materials of greater than or equal to about 2 layers, greater than or equal to about 3 layers, and less than or equal to about 10 layers or less than or equal to about 5 layers. In an embodiment, the second electrode (or a cathode) may be a multilayer electrode including electrode materials of greater than or equal to about 2 layers, greater than or equal to about 3 layers, and less than or equal to about 10 layers or less than or equal to about 5 layers.

The multilayer electrode may include, for example, a light-transmitting conductive material such as indium tin oxide, a non-light-transmitting conductive material such as aluminum (or a reflective electrode material), or a combination thereof. In an embodiment, an electrode (for example, an anode or a cathode) may have a structure in which a non-light-transmitting conductive material (or a reflective electrode material layer) is disposed between light-transmitting conductive materials (for example, light-transmitting conductive material layers). In an embodiment, an electrode (an anode or a cathode) may have a structure in which a light-transmitting conductive material (for example, a light-transmitting conductive material layer) is disposed between non-light-transmitting conductive materials (or reflective electrode materials).

When a voltage is applied between the first electrode and the second electrode, the emission layer may emit light upward and downward by an electric field, and light traveling toward a reflective electrode may be reflected and emitted in an opposite direction.

In an embodiment, light may be emitted toward the cathode. In an embodiment, light may be emitted toward the anode.

A thickness of the electrode (the first electrode and/or the second electrode) is not particularly limited and may be appropriately selected in consideration of device efficiency. For example, the thickness of the electrode may be greater than or equal to about 5 nm, for example, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), for example, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, less than or equal to about 100 nm, less than or equal to about 90 nm, less than or equal to about 80 nm, less than or equal to about 70 nm, or less than or equal to about 60 nm.

A method of forming the electrode is not particularly limited and may be appropriately selected depending on a material. In an embodiment, the electrode may be formed by deposition, coating, or a combination thereof, but is not limited thereto.

An emission layer 3 or 30 is disposed between the first electrode 1 and the second electrode 5 (for example, an anode 10 and a cathode 50). The emission layer comprises semiconductor nanoparticles (for example, blue light-emitting nanoparticles, red light-emitting nanoparticles, or green light-emitting nanoparticles). The emission layer may include one or more (for example, greater than or equal to about 2 or greater than or equal to about 3 and less than or equal to about 10) monolayers of a plurality of nanoparticles.

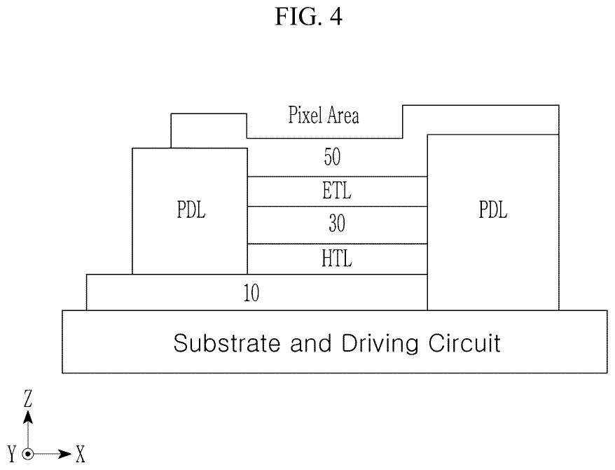

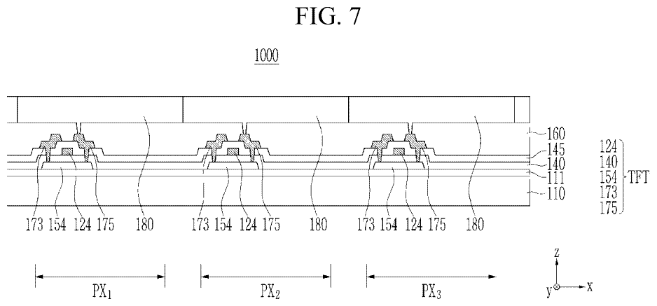

The emission layer may be patterned. In an embodiment, the patterned emission layer may include a blue emission layer 30B (for example, disposed in a blue pixel in a display device described below), a red emission layer 30R (for example, disposed in a red pixel in the display device described below), a green emission layer 30G (for example, disposed in a green pixel in the display device described below), or a combination thereof. Each emission layer may be separated (for example, optically) from an adjacent emission layer by a partition wall. In an embodiment, a partition wall or a bank such as a black matrix or a pixel definition layer (PDL) may be disposed between red emission layer(s), green emission layer(s), and blue emission layer(s) (see FIGS. 4 and 7). In a non-limiting embodiment, the red emission layer, the green emission layer, and the blue emission layer may each be optically substantially isolated.

The emission layer may not include cadmium. The emission layer or the semiconductor nanoparticle may not include mercury, lead, or a combination thereof. The semiconductor nanoparticle may further include or may not include copper, manganese, or a combination thereof. The semiconductor nanoparticle included in the emission layer may include the surface-treated semiconductor nanoparticle described herein.

Forming the emission layer may be performed by any wet method (for example, coating or inkjet printing). Forming the emission layer may include applying an ink composition according to an embodiment onto a substrate (for example, a hole auxiliary layer or an electron auxiliary layer) by an appropriate method and, optionally, removing a liquid vehicle.

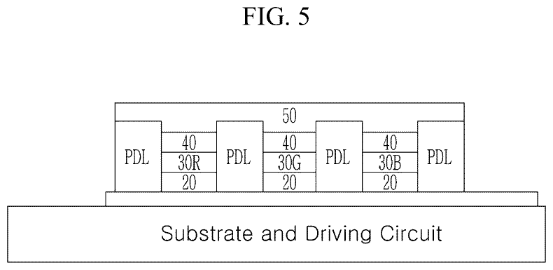

Forming the emission layer by inkjet printing may include loading an ink composition containing a semiconductor nanoparticle into equipment equipped with an inkjet printing nozzle and ejecting/depositing droplets of the composition from the nozzle toward a desired position (for example, a surface of a hole transport layer or an electron transport layer defined by a pixel definition layer (PDL) or a partition wall or bank) (see FIGS. 4 and 5).

In an electroluminescent device of an embodiment, a thickness of the emission layer may be appropriately selected. In an embodiment, the emission layer may include monolayer(s) of the semiconductor nanoparticles. In an embodiment, the emission layer may include monolayers of the semiconductor nanoparticles in an amount of greater than or equal to about 1 layer, for example, greater than or equal to about 2 layers, greater than or equal to about 3 layers, or greater than or equal to about 4 layers, and less than or equal to about 20 layers, less than or equal to about 10 layers, less than or equal to about 9 layers, less than or equal to about 8 layers, less than or equal to about 7 layers, or less than or equal to about 6 layers. The emission layer may have a thickness of greater than or equal to about 5 nm, for example, greater than or equal to about 10 nm, greater than or equal to about 20 nm, or greater than or equal to about 30 nm, and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The emission layer may have a thickness of, for example, about 10 nm to about 150 nm, about 20 nm to about 100 nm, or about 30 nm to about 50 nm.

Forming an emission layer 13 including semiconductor nanoparticles may be performed by obtaining a composition including a semiconductor nanoparticle and an organic solvent and applying or depositing the composition onto a substrate or a charge auxiliary layer by an appropriate method (for example, spin coating or inkjet printing).

Forming the emission layer may further include thermally treating the applied or deposited semiconductor nanoparticle layer. A heat treatment temperature is not particularly limited and may be appropriately selected in consideration of a boiling point of the organic solvent. For example, the heat treatment temperature may be greater than or equal to about 60° C., for example, greater than or equal to about 70° C., and less than or equal to about 250° C., or less than or equal to about 180° C. A type of the organic solvent is not particularly limited and may be appropriately selected. In an embodiment, the organic solvent may include a (substituted or unsubstituted) aliphatic hydrocarbon organic solvent, a (substituted or unsubstituted) aromatic hydrocarbon organic solvent, an acetate solvent, or a combination thereof.

In an embodiment, the emission layer may be a single layer or a multi-layered structure having at least two layers. In the multi-layered structure, adjacent layers (e.g., a first emission layer and a second emission layer) may be configured to emit a first light (e.g., green light, blue light, or red light). In the multi-layered structure, adjacent layers (e.g., a first emission layer and a second emission layer) may have the same or different composition, ligands, or a combination thereof. In an embodiment, the (multi-layered) light-emitting layer may have a halogen amount that varies (increase or decrease) in a thickness direction. In an embodiment, in the (multi-layered) light-emitting layer, the amount of the halogen may increase in a direction toward the electron auxiliary layer. In the (multi-layered) emission layer, an amount, or a content of an organic ligand may decrease in the direction toward the electron auxiliary layer. In the (multi-layered) emission layer, the amount, or the content of the organic ligand may increase in the direction toward the electron auxiliary layer.

The electroluminescent device may further include a charge (hole or electron) auxiliary layer between the first electrode and the second electrode (e.g., an anode and a cathode). In an embodiment, the electroluminescent device may include a hole auxiliary layer 20 or an electron auxiliary layer 40 between the anode 10 and the emission layer 30, between the cathode 50 and the emission layer 30, or a combination thereof. (See FIGS. 2 and 3.)

The light emitting device according to an embodiment may further include a hole auxiliary layer. The hole auxiliary layer 20 may be disposed between the first electrode 10 and the emission layer 30. The hole auxiliary layer 20 may include a hole injection layer, a hole transport layer, an electron blocking layer, or a combination thereof. The hole auxiliary layer 20 may be a layer of a single component or a multilayer structure in which adjacent layers include different components.

The hole auxiliary layer 20 may have a HOMO energy level that may be matched with the HOMO energy level of the emission layer 30 in order to enhance mobility of holes transferred from the hole auxiliary layer 20 to the emission layer 30. In an embodiment, the hole auxiliary layer 20 may include a hole injection layer close to the first electrode 10 and a hole transport layer close to the emission layer 30.

The material included in the hole auxiliary layer 20 (e.g., a hole transport layer, a hole injection layer, or an electron blocking layer) is not particularly limited, and may include, for example, poly(9,9-dioctyl-fluorene-co-N-(4-butylphenyl)-diphenylamine) (“TFB”), polyarylamine, poly(N-vinylcarbazole), poly(3,4-ethylenedioxythiophene) (‘PEDOT”), poly(3,4-ethylenedioxythiophene):polystyrene sulfonate (“PEDOT:PSS”), polyaniline, polypyrrole, N,N,N′,N′-tetrakis(4-methoxyphenyl)-benzidine (“TPD”), 4,4′-bis[N-(1-naphthyl)-N-phenyl-amino]biphenyl (“α-NPD”), 4,4′,4″-Tris[phenyl(m-tolyl)amino]triphenylamine (m-MTDATA), 4,4′,4″-tris(N-carbazolyl)-triphenylamine (“TCTA”), 1,1-bis[(di-4-toylamino)phenyl]cyclohexane (“TAPC”), a p-type metal oxide (e.g., NiO, WO₃, MoO₃, etc.), a carbon-containing material such as graphene oxide, or a combination thereof, but is not limited thereto.

In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

The electron auxiliary layer 40 may be disposed between the emission layer 30 and the second electrode 50. The electron auxiliary layer 40 may include, for example, an electron injection layer, an electron transport layer, a hole blocking layer, or a combination thereof. The electron auxiliary layer may include, for example, an electron injection layer (“EIL”) that facilitates injection of electrons, an electron transport layer (“ETL”) that facilitates transport of electrons, a hole blocking layer (“HBL”) that blocks the movement of holes, or a combination thereof.

In an embodiment, the electron injection layer may be disposed between the electron transport layer and the cathode (the second electrode). For example, the hole blocking layer may be disposed between the emission layer and the electron transport (injection) layer but is not limited thereto. The thickness of each layer may be selected appropriately. For example, the thickness of each layer may be greater than or equal to about 1 nm and less than or equal to about 500 nm, but is not limited thereto. The electron injection layer may be an organic layer formed by vapor deposition. The electron transport layer may include an inorganic oxide nanoparticle or may be an organic layer formed by vapor deposition.

The electron transport layer (“ETL”), the electron injection layer, the hole blocking layer, or a combination thereof may include, for example, 1,4,5,8-naphthalene-tetracarboxylic dianhydride (“NTCDA”), bathocuproine (“BCP”), tris[3-(3-pyridyl)-mesityl]borane (“3TPYMB”), LiF, tris(8-hydroxyquinoline)aluminum (“Alq₃”), tris(8-hydroxyquinoline) gallium (“Gaq₃”), tris-(8-hydroxyquinoline) indium (“Inq₃”), bis(8-hydroxyquinoline) zinc (“Znq₂”), bis(2-(2-hydroxyphenyl)benzothiazolate) zinc (“Zn(BTZ)₂”), bis(10-hydroxybenzo[h]quinolinato) beryllium (“BeBq₂”), 8-(4-(4,6-di(naphthalen-2-yl)-1,3,5-triazin-2-yl)phenyl) quinolone (“ET204”), 8-hydroxyquinolinato lithium (“Liq”), an n-type metal oxide (e.g., ZnO, HfO₂, etc.) or a combination thereof, but is not limited thereto.

The electron auxiliary layer 40 may include an electron transport layer. The electron transport layer may include a plurality of nanoparticles. The plurality of nanoparticles may include a metal oxide containing zinc.

The metal oxide may include zinc oxide, zinc magnesium oxide, or a combination thereof. The metal oxide may include Zn₁₋ₓMₓO, wherein Mis Mg, Ca, Zr, W, Li, Ti, Y, Al, or a combination thereof and 0≤x≤0.5. In an embodiment, the M in the formula Zn₁₋ₓMₓO may be magnesium (Mg). In an embodiment, in the formula Zn₁₋ₓMₓO, the x may be greater than or equal to about 0.01 and less than or equal to about 0.3, for example, less than or equal to about 0.25, less than or equal to about 0.2, or less than or equal to about 0.15.

The absolute value of the LUMO of the aforementioned nanostructures included in the emission layer may be greater or smaller than the absolute value of the LUMO of the metal oxide. The average size of the nanoparticles may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm.

In an embodiment, each thickness of the electron auxiliary layer 40 (e.g., electron injection layer, electron transport layer, or hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

A device according to an embodiment may have a normal structure. In an embodiment, in the device, the anode (the first electrode) 10 disposed on the transparent substrate 100 may include a metal oxide containing transparent electrode (e.g., an ITO electrode), and the cathode (the second electrode) 50 facing the anode 10 may include a conductive metal (e.g., having a relatively low work function, such as Mg, Al, etc.). The hole auxiliary layer 20 (e.g., a hole injection layer such as PEDOT:PSS, p-type metal oxide, or a combination thereof; a hole transport layer such as TFB, polyvinylcarbazole (“PVK”), or a combination thereof, or a combination thereof) may be provided between the transparent electrode 10 and the emission layer 30. The hole injection layer may be disposed close to the transparent electrode and the hole transport layer may be disposed close to the light emitting layer (or the emission layer). The electron auxiliary layer 40 such as an electron injection/transport layer may be disposed between the emission layer 30 and the cathode 50 (See FIG. 2).

A device according to an embodiment may have an inverted structure. Herein, the cathode 50 disposed on the transparent substrate 100 may include a metal oxide containing transparent electrode (e.g., ITO), and the anode 10 facing the cathode may include a metal (e.g., having a relatively high work function, such as Au, Ag, etc.). For example, an (optionally doped) n-type metal oxide (crystalline Zn metal oxide) or the like may be disposed as an electron auxiliary layer 40 (e.g., an electron transport layer) between the second electrode 50 and the emission layer 30, a hole auxiliary layer 20 (e.g., a hole transport layer including TFB, PVK, or a combination thereof; a hole injection layer including MoO₃ or other p-type metal oxide; or a combination thereof) may be disposed between the metal anode 10 and the emission layer 30 (See FIG. 3).

The aforementioned device may be manufactured by an appropriate method. For example, the electroluminescent device may be manufactured by optionally forming a hole auxiliary layer (e.g., by deposition or coating) on a substrate on which an electrode is disposed, forming a emission layer including nanostructures (e.g., a pattern of the aforementioned nanostructures), and forming (optionally, an electron auxiliary layer and) an electrode (e.g., by vapor deposition or coating) on the light emitting layer. A method of forming the electrode/hole auxiliary layer/electron auxiliary layer may be appropriately selected and is not particularly limited.

In an embodiment, each layer included in the hole transport region, the light-emitting layer, and each layer included in the electron transport region may be formed in a predetermined region using various methods such as vacuum deposition, spin coating, casting, Langmuir-Blodgett (LB) method, inkjet printing, laser printing, and Laser Induced Thermal Imaging (LITI). For example, the light-emitting layer may be formed by inkjet printing. The inkjet printing process is as described herein.

When each layer included in the hole transport region, the light-emitting layer, and each layer included in the electron transport region is formed by vacuum deposition, the deposition conditions may be appropriately selected. For example, the deposition temperature may be about 100° C. to about 500° C., the vacuum degree may be about 10\hat{ }-8 to about 10\hat{ }-3 torr, and the deposition rate range may be about 0.01 to about 100 angstroms per second (Å/sec). The deposition conditions may be selected in consideration of the material to be included in the layer to be formed and the structure of the layer to be formed.

The electroluminescent device may be configured to emit blue light. The wavelength range of the blue light is as described herein. The electroluminescent device may be configured to emit green light. The wavelength range of the green light is as described herein. The electroluminescent device may be configured to emit red light. The wavelength range of the red light is as described herein.

In the electroluminescent device of an embodiment, a maximum external quantum efficiency (“EQE”) may be greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. In the electroluminescent device of an embodiment, a maximum external quantum efficiency (‘EQE”) may be less than or equal to about 50%, less than or equal to about 40%, less than or equal to about 30%, or less than or equal to about 20%.

The electroluminescent device may have a maximum luminance of greater than or equal to about 40,000 nits (cd/m²), greater than or equal to about 50,000 nits, greater than or equal to about 60,000 nits, greater than or equal to about 70,000 nits, greater than or equal to about 80,000 nits, greater than or equal to about 90,000 nits, greater than or equal to about 95,000 nits, greater than or equal to about 100,000 nits, greater than or equal to about 105,000 nits, greater than or equal to about 110,000 nits, greater than or equal to about 115,000 nits, greater than or equal to about 120,000 nits, or greater than or equal to about 125,000 nits. The maximum luminance may be in the range of about 3,000 nits to about 500,000 nits.

The electroluminescent device may exhibit improved lifespan. In an embodiment, the lifespan of the electroluminescent device may be measured while being driven at a predetermined initial luminance (e.g., 146 nits or 650 nits).

The lifespan T50 of the electroluminescent device may be greater than or equal to about 10 hours, greater than or equal to about 50 hours, greater than or equal to about 80 hours, greater than or equal to about 100 hours, greater than or equal to about 120 hours, greater than or equal to about 130 hours, greater than or equal to about 150 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1,000 hours, greater than or equal to about 1,500 hours, or more.

The lifespan T90 of the electroluminescent device may be greater than or equal to about 10 hours, greater than or equal to about 15 hours, greater than or equal to about 20 hours, greater than or equal to about 25 hours, greater than or equal to about 30 hours, greater than or equal to about 35 hours, greater than or equal to about 40 hours, greater than or equal to about 50 hours, greater than or equal to about 75 hours, greater than or equal to about 100 hours, greater than or equal to about 125 hours, greater than or equal to about 150 hours, greater than or equal to about 175 hours, greater than or equal to about 200 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1,000 hours, greater than or equal to about 1,500 hours, or more.

In an embodiment, T50 may be in the range of about 150 hours to about 5,000 hours, about 400 hours to about 4,000 hours, about 500 hours to about 3,500 hours, about 750 hours to about 2,000 hours, about 1,000 hours to about 1,500 hours, or a combination thereof.

In an embodiment, T90 may be in the range of about 13 hours to about 5,000 hours, about 15 hours to about 2,800 hours, about 18 hours to about 1,200 hours, about 22 hours to about 1,000 hours, about 31 hours to about 800 hours, about 50 hours to about 700 hours, about 60 hours to about 500 hours, about 80 hours to about 400 hours, or a combination thereof.

In an embodiment, a display device comprises the electroluminescent device described herein.

The display device may include a first pixel and a second pixel that is configured to emit light different from the light of the first pixel.

The display device (e.g., a display panel) may include a first pixel and a second pixel configured to emit light of a color different from that of the first pixel. In one embodiment, the first light emitted from the light-emitting layer may be extracted through the second electrode (e.g., in the Z direction) (see FIG. 4 or FIG. 5). In an embodiment, the first light may be extracted through the (transparent) first electrode and optionally through the substrate 100 (see FIG. 3). The light-emitting layer may be disposed within a pixel (or subpixel) in the display device (display panel) as described below (see FIG. 4 or FIG. 5).

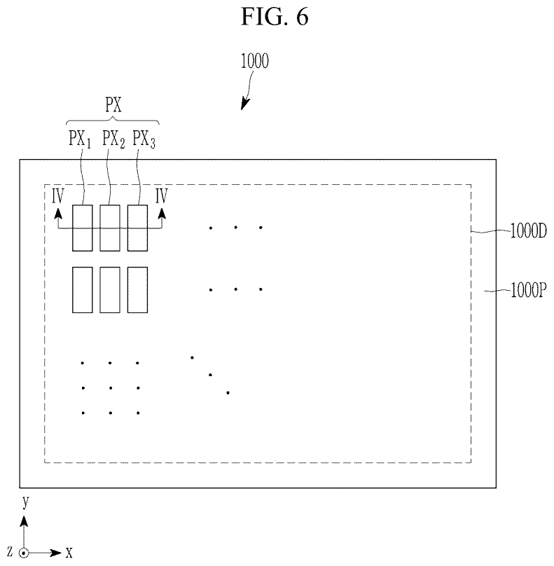

Referring to FIG. 6, a display panel 1000 according to an embodiment may include a display area 1000D for displaying an image and a non-display area 1000P disposed around the display area 1000D, in which the binding element may be located.

The display area 1000D may include a plurality of pixels PXs arranged along a row (e.g., x direction) and/or a column (e.g., y direction), and each pixel PX may include a plurality of sub-pixels PX₁, PX₂, and PX₃ displaying different colors. As an example, a configuration in which three sub-pixels PX₁, PX₂, and PX₃ constitute one pixel PX is illustrated, but the configuration is not limited thereto. An additional sub-pixel such as a white sub-pixel may be further included in the display area 1000D, and one or more sub-pixel displaying the same color may be included in the display area 1000D. The plurality of pixels PXs may be arranged in, for example, a Bayer matrix, a PenTile matrix, and/or a diamond matrix, but is not limited thereto.

Each of the sub-pixels PX₁, PX₂, and PX₃ may be configured to display a color of three primary colors or a combination of three primary colors, for example, red, green, blue, or a combination thereof (e.g., white light). For example, the first sub-pixel PX₁ may be configured to display red, the second sub-pixel PX₂ may be configured to display green, and the third sub-pixel PX₃ may be configured to display blue.

In the figure, each of the sub-pixels are depicted to have the same size, but the present disclosure is not limited thereto. For example, at least one of the sub-pixels may be larger or smaller, or have a different shape, than another sub-pixel.

In an embodiment, the display panel of an embodiment may include a light emitting panel which may include a lower substrate 110, a buffer layer 111, a thin film transistor TFT, and a light emitting element 180. The display panel may further include a circuit element for switching and/or driving each of the light emitting elements.

Referring to FIG. 7, in the light emitting panel of an embodiment, the light emitting element 180 may be disposed for each sub-pixel PX₁, PX₂, and PX₃. The light emitting element 180 disposed in each sub-pixel PX₁, PX₂, and PX₃ may be independently driven. The subpixel may include a blue subpixel, red subpixel, or a green subpixel. At least one of the light emitting element 180 may be an electroluminescent element according to an embodiment described herein.

Details of the substrate are the same as described herein. The buffer layer 111 may include an organic material, an inorganic material, or an organic-inorganic material. The buffer layer 111 may include, for example, an oxide, a nitride, or an oxynitride, and may include, for example, silicon oxide, silicon nitride, silicon oxynitride, or a combination thereof, but is not limited thereto. The buffer layer 111 may be one layer or two or more layers and may cover a portion of or the entire surface of the lower substrate 110. The buffer layer 111 may be omitted.

The thin film transistor TFT may be a three terminal element for switching and/or driving the light emitting element 180, and one or two or more thin film transistor(s) TFT may be included for each sub-pixel. The thin film transistor TFT may include a gate electrode 124, a semiconductor layer 154 overlapped with the gate electrode 124, a gate insulating layer 140 between the gate electrode 124 and the semiconductor layer 154, and a source electrode 173 and a drain electrode 175 electrically connected to the semiconductor layer 154. A coplanar top gate structure is shown as an example, but the structure is not limited thereto and the thin film transistor TFT may have various structures.

The gate electrode 124 is electrically connected to a gate line (not shown), and may include, for example, a low-resistance metal such as aluminum (Al), molybdenum (Mo), copper (Cu), titanium (Ti), silver (Ag), gold (Au), an alloy thereof, or a combination thereof, but is not limited thereto.

The semiconductor layer 154 may be an inorganic semiconductor such as amorphous silicon, polycrystalline silicon, or oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but they are not limited thereto. The semiconductor layer 154 may include a channel region and doped regions disposed on both sides of the channel region and electrically connected to the source electrode 173 and the drain electrode 175, respectively.

The gate insulating layer 140 may include an organic material, an inorganic material, or an organic-inorganic material, and may include, for example, an oxide, a nitride, or an oxynitride, and may include, for example, silicon oxide, silicon nitride, silicon oxynitride, or a combination thereof, but is not limited thereto. In the drawing, an example in which the gate insulating layer 140 is formed on the entire surface of the substrate 110 is illustrated, but the present disclosure is not limited thereto and the gate insulating layer 140 may be selectively formed between the gate electrode 124 and the semiconductor layer 154. The gate insulating layer 140 may be formed of one or two or more layers.

The source electrode 173 and the drain electrode 175 may include, for example, a low-resistance metal such as aluminum (Al), molybdenum (Mo), copper (Cu), titanium (Ti), silver (Ag), gold (Au), an alloy thereof, or a combination thereof, but are not limited thereto. The source electrode 173 and the drain electrode 175 may be electrically connected to the doped regions of the semiconductor layer 154, respectively. The source electrode 173 may be electrically connected to a data line (not shown), and the drain electrode 175 is electrically connected to a light emitting element 180.

An interlayer insulating layer 145 may be additionally formed between the gate electrode 124 and the source/drain electrodes 173 and 175. The interlayer insulating layer 145 may include an organic material, an inorganic material, or an organic-inorganic material, for example, oxide, nitride, or oxynitride, for example, silicon oxide, silicon nitride, silicon oxynitride, or a combination thereof, but is not limited thereto. The interlayer insulating layer 145 may be formed of one or two or more layers.

A protective layer 160 may be formed on the thin film transistor TFT. The protective layer 160 may be, for example, a passivation layer. The protective layer 160 may include an organic material, an inorganic material, or an organic-inorganic material, for example, polyacrylic, polyimide, polyamide, poly(amide-imide), or a combination thereof, but is not limited thereto. The protective layer 160 may be formed of one or two or three or more layers.

In an embodiment, one of the first electrode 1, 10 and the second electrode 5, 50, may be a pixel electrode linked to the TFT and the other of them may be a common electrode.

In an embodiment, the light emitting device or the display device including the same may be used in a top emission type, a bottom emission type, a dual emission type, or a combination thereof.

In an embodiment, the first electrode 1, 10 may be a light transmitting electrode and the second electrode 5, 50 may be a reflective electrode, and the display panel may be a bottom emission type display panel that emits light toward the first electrode 1, 10 and the lower substrate 110, 100, if present. In an embodiment, the first electrode 1, 10 may be a reflective electrode and the second electrode 5, 50 may be a light transmitting electrode, and the display panel may be a top emission type display panel that emits light to the opposite side of the first electrode 1, 10 and the lower substrate 100, 110 if present. In an embodiment, both the first electrode and the second electrode may be translucent electrodes, and the display panel 1000 may be a both side emission type display panel that emits light on the substrate side and on the opposite side of the substrate.

The display device or an electronic apparatus may include (or may be) a device or apparatus such as a television, a virtual reality/augmented reality (VR/AR), a handheld terminal, a monitor, a notebook computer, an electronic display board, a camera, or a part for an automatic, e.g., autonomous, vehicle.

Specific examples are described below. However, the examples described below are only for specifically illustrating or explaining the disclosure, and the scope of the disclosure is not limited thereto.

### EXAMPLES

### 1. Photoluminescence (PL) Analysis and TRPL Analysis

The photoluminescence spectrum and absolute QY of the nanoparticles were obtained at room temperature with an excitation wavelength of 372 nm using a Hitachi F-7000 spectrophotometer or a Hamamatsu QY instrument (Quantaurus-QY Absolute PL quantum yield spectrophotometer C11347-11).

### 2. GC Analysis

Gas chromatography analysis was performed using an Agilent GC-MS 7890B/5977A. No standard substances were used. After separating the crude containing the manufactured semiconductor nanoparticles twice with ethanol (EtOH) and vacuum drying, 0.1 mg of the manufactured semiconductor nanoparticles and 1 microliter (μL) of TMAH (tetramethylammonium hydroxide) were mixed and left in the hood for 2 minutes before performing py-GC/MS measurement.
Pyrolyzer: 450° C.
Column: 30 m×0.25 mm×0.25 mm (UA5)
Flow: He (1 mL/min)
Inlet temperature: 300° C.
Oven temperature: 50° C. (held for 2 min), increases up to 320° C. at 20° C./min (held for 10 min)
Analyzer: quadrupole (range: 10 to 550 m/z)

### 3. Thermogravimetric Analysis (TGA)

A thermogravimetric analysis was performed using a Trios V3.2 system (TA Instruments) under nitrogen gas at a heating rate of 10° C./min from 20° C. to 600° C. The weight loss from 200° C. to 550° C. was measured as the organic content.

### 4. Electroluminescence Measurement

A current according to an applied voltage is measured with a Keithley 2635B source meter, and a CS2000 spectrometer is used to measure electroluminescent properties (e.g., luminance and EQE) of a light-emitting device.

### 5. Lifespan

T90(h): The time (hours) it takes for the luminance to decrease to 90% of the initial luminance when a device is driven at a predetermined luminance (e.g., 650 nits or 146 nits) was measured.

T50(h): The time (hours) it takes for the luminance to decrease to 50% of the initial luminance when a device is driven at a predetermined luminance (e.g., 650 nits or 146 nits) was measured.

The following synthesis is performed under an inert gas atmosphere (e.g., under nitrogen) unless otherwise specified. A precursor content is provided as a molar content, unless otherwise specified.

### Reference Example 1

(1) Selenium (Se), sulfur(S), and tellurium (Te) were dispersed in trioctylphosphine (TOP) to obtain a 2 mole per liter (M) Se/TOP stock solution, a 1M S/TOP stock solution, and a 0.1M Te/TOP stock solution.

In a 300 milliliter (mL) reaction flask containing trioctylamine (TOA), 4.5 millimole (mmol) of zinc acetate was added with oleic acid and heated to 120° C. under vacuum. After 1 hour, the atmosphere in the reactor was switched to an inert gas.

After heating to 240° C. to 300° C., the prepared Se/TOP stock solution and Te/TOP stock solution were quickly injected into the reactor at a Te:Se ratio of 1:15. The reaction was carried out for 40 minutes. After the reaction was completed, ethanol was added to the reaction solution, which was quickly cooled to room temperature, and centrifuged to obtain ZnTeSe semiconductor nanocrystals. The obtained precipitate was dispersed in hexane to obtain ZnSeTe cores. An average size of the cores was approximately 3 nm.

In a 300 mL reaction flask containing TOA, zinc acetate was added with oleic acid and vacuum-treated at 120° C. The nitrogen (N₂) was flowed into the flask, and then the flask was heated to the reaction temperature (340° C.). The hexane dispersion of the ZnSeTe cores was quickly added to the reaction flask, followed by the addition of the Se/TOP stock solution to proceed with the reaction. Regarding the formation of the ZnSe shell, the amount of selenium precursor relative to 1 mole of the zinc precursor was 0.67 moles. After the reaction was completed, the reactor was cooled to room temperature, and ethanol was added to the reaction solution to precipitate nanoparticles containing the first semiconductor nanocrystal (ZnTeSe) and the second semiconductor nanocrystal (ZnSe). The precipitate was recovered by centrifugation, and it was confirmed that the obtained nanoparticles could be dispersed in hydrocarbon solvents such as octane.

(2) In trioctylamine, zinc acetate and ethyl hexanoic acid (CAS No. 149-57-5, Sigma-Aldrich, Molecular weight: 144.24 g/mol) of the following structure were each added (at a mole ratio between zinc acetate and ethyl hexanoic acid of 1:2) and heated to 120° C. under vacuum for 1 hour to prepare the first zinc precursor:

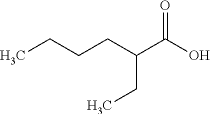

In trioctylamine, zinc acetate and oleic acid of the following structure were each added (at a mole ratio between zinc acetate and oleic acid of 1:2) and heated to 120° C. under vacuum for 1 hour to prepare the second zinc precursor:

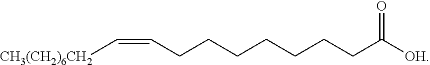

Trioctylamine was added to a 300 mL reaction flask and heated to 120° C. under vacuum for 1 hour, and the nitrogen (N₂) was flowed into the flask. While raising the flask temperature to the reaction temperature (340° C.), the octane dispersion of the particles prepared in the reference example was added, followed by the first zinc precursor and dodecanethiol (sulfur precursor) each injected in two portions.

After 30 minutes, while adjusting the reaction temperature to 250° C. to 300° C., zinc chloride and the second zinc precursor were added. The total reaction time was 70 minutes.

A mole ratio of a first zinc precursor, a second zinc precursor, and a sulfur precursor (first zinc precursor:second zinc precursor:sulfur precursor) was 2.1:0.4:1.4. A mole ratio of a total amount of the zinc precursor used to zinc chloride was 2.5:0.4.

The reactor was cooled to room temperature, ethanol was added to a reaction solution to promote precipitation of semiconductor nanoparticles, and the semiconductor nanoparticles were recovered by centrifugation. The obtained semiconductor nanoparticles were dispersed in hexane or octane to obtain a QD dispersion.

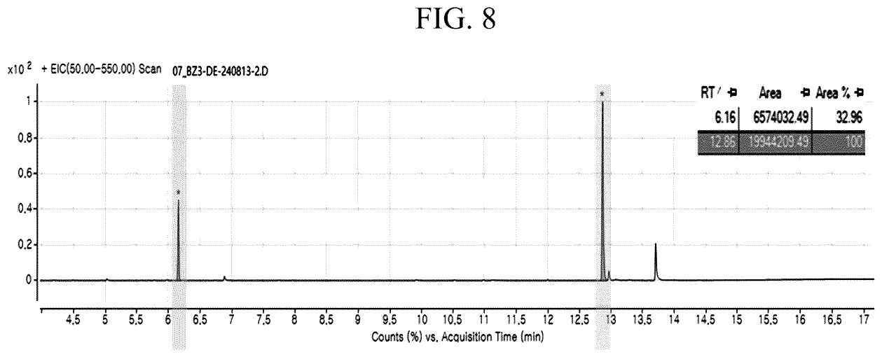

Gas chromatography (GC) analysis was performed on the obtained semiconductor nanoparticles, and the results are summarized in FIG. 8. According to the results of FIG. 8, a first peak assigned to an ethylhexanoate ester moiety at a retention time of 6.16 minutes and a second peak assigned to an oleate ester moiety at a retention time of 12.86 minutes were respectively identified, and a second organic ligand fraction calculated from a corrected area of the first peak (in consideration of a molecular weight) and a corrected area of the second peak (in consideration of a molecular weight) was 60.8%.

As a result of performing thermogravimetric analysis (TGA) on the obtained semiconductor nanoparticles, it was confirmed that a weight decrease (that is, an organic content) in a range of greater than or equal to about 200° C. to less than or equal to about 550° C. was 9.3 weight %, based on a total weight of the semiconductor nanoparticles.

### Reference Example 2: Synthesis of ZnMgO Nanoparticles

Zinc acetate dihydrate and magnesium acetate tetrahydrate are added to a reactor containing dimethylsulfoxide and heated at 60° C. in air. Subsequently, an ethanol solution of tetramethylammonium hydroxide pentahydrate is added to the reactor. After stirring the mixture for 1 hour, a precipitate form and is separated from the reaction mixture with a centrifuge. The precipitate is dispersed in ethanol to obtain Zn₁₋ₓMgₓO nanoparticles. (x=0.15) The obtained nanoparticles are subjected to a transmission electron microscope analysis. The particles have an average size of about 3 nm.

### Preparation Example 1: Treatment for Semiconductor Nanoparticle

A QD dispersion prepared in Reference Example 1 was added to a liquid medium (cyclohexyl benzene) and stirred to prepare a first dispersion. Zinc chloride was dissolved in acetone to prepare a zinc chloride solution. The zinc chloride solution was added to the first dispersion under stirring to precipitate semiconductor nanoparticles. A temperature of the obtained mixture was heated to 150° C., and a surface exchange reaction was performed by dropwise adding ethylhexanoic acid under stirring. As the surface-treated semiconductor nanoparticles were redispersed in the liquid medium, a transparent second dispersion was obtained.

Ethanol was added to the obtained second dispersion to promote precipitation, and a precipitate was recovered by centrifugation.

A total amount of zinc chloride used for surface treatment was adjusted such that a concentration in the first dispersion was 0.03 M. An amount of ethylhexanoic acid was 100 mole % of zinc chloride (that is, 1 mole of an organic ligand per 1 mole of zinc chloride).

Photoluminescence analysis was performed on the surface-treated semiconductor nanoparticles, and the results are summarized in Table 1.

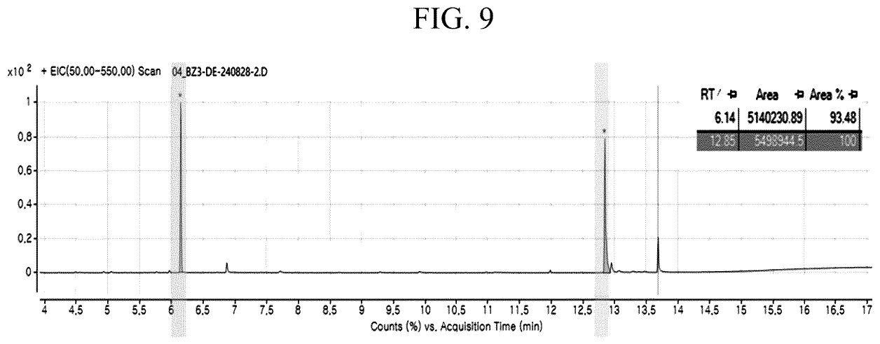

Gas chromatography (GC) analysis was performed on the surface-treated semiconductor nanoparticles, and the results are summarized in FIG. 9. According to the results of FIG. 9, a first peak assigned to an ethylhexanoate ester moiety at a retention time of 6.14 minutes and a second peak assigned to an oleate ester moiety at a retention time of 12.85 minutes were respectively identified, and a percentage of a corrected area of the second peak with respect to a total of a corrected area of the first peak and a corrected area of the second peak (that is, a second organic ligand fraction) was 35%.

As a result of performing thermogravimetric analysis (TGA) on the obtained semiconductor nanoparticles, it was confirmed that a weight decrease (that is, an organic content) in a range of greater than or equal to about 200° C. to less than or equal to about 550° C. was 7.4 weight %, based on a total weight of the semiconductor nanoparticles.

TABLE 1

| | | Amount of | % Oleic acid to |
|---|---|---|---|
| | PLQY | organics | total ligand |
| Ref. Example 1 | 90.2% | 9.3% | 60.8% |
| Prep. Example 1 | 91.3% | 7.4% | 35% |

PLQY: quantum yield

From the results of Table 1, it was confirmed that the surface-treated semiconductor nanoparticle of Preparation Example 1 may exhibit an improved PLQY.

It was confirmed that the surface-treated semiconductor nanoparticle may maintain a colloidal dispersion state (that is, a transparent dispersion) in octane or cyclohexylbenzene.

### Preparation Example 2: Semiconductor Nanoparticle Treatment

Surface-treated semiconductor nanoparticles were obtained in the same manner as in Preparation Example 1, except that a concentration of zinc chloride in the first dispersion was adjusted to 0.2 M.

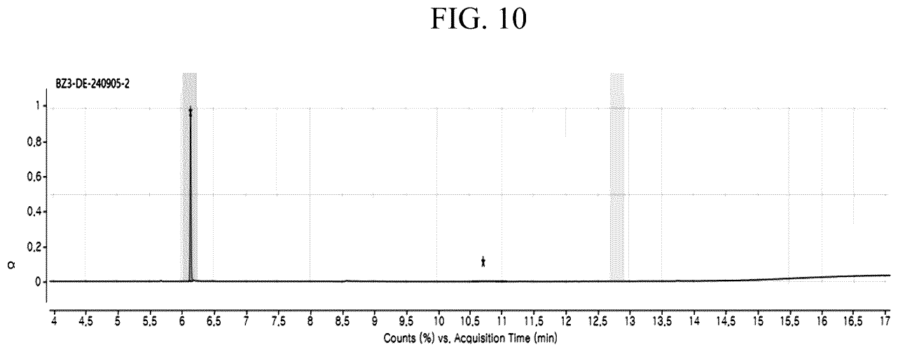

Gas chromatography (GC) analysis was performed on the surface-treated semiconductor nanoparticles, and the results are summarized in FIG. 10. According to the results of FIG. 10, only a first peak assigned to an ethylhexanoate ester moiety at a retention time of 6.14 minutes was identified, and a second peak assigned to an oleate ester moiety was not identified (in other words, a percentage of an area of the second peak with respect to a total area of the first peak and the second peak was 0%).

As a result of performing thermogravimetric analysis (TGA) on the obtained semiconductor nanoparticles, it was confirmed that a weight decrease (that is, an organic content or amount of organics) in a range of greater than or equal to about 200° C. to less than or equal to about 550° C. was 4.7 weight %, based on a total weight of the semiconductor nanoparticles. It was confirmed that the surface-treated semiconductor nanoparticles may maintain a colloidal dispersion state in cyclohexylbenzene.

### Device Example

### Example 1

Using the semiconductor nanoparticles prepared in Preparation Example 1, a light emitting device having a structure of ITO/PEDOT:PSS (300 angstrom)/TFB (250 angstrom)/a semiconductor nanoparticle emission layer (360 angstrom)/ZnMgO (240 angstrom)/Al was fabricated in the following manner, and electroluminescent properties were measured.

On a glass substrate on which an ITO electrode (a first electrode) was deposited, PEDOT:PSS and a TFB (or PVK) layer were formed as a hole injection layer and a hole transport layer by a spin coating method. On the formed TFB layer (25 nm), a semiconductor nanoparticle solution (an octane dispersion) prepared in Preparation Example 1 was spin-coated to form an emission layer. On the emission layer, a zinc magnesium oxide nanoparticle layer was formed as an electron auxiliary layer, and thereafter an Al electrode was formed by deposition to fabricate a light emitting device.

Electroluminescent properties and lifetime were measured for the fabricated device. The electroluminescent properties are summarized in Table 2 below.

### Comparative Example 1

An electroluminescent device was fabricated in the same manner as in Example 1, except that the semiconductor nanoparticles prepared in Reference Example 1 were used. Electroluminescent properties and lifetime of the fabricated device were measured, and the results are summarized in Table 2 below.

TABLE 2

| | Relative EQE | Relative EQE | Relative | Relative |
|---|---|---|---|---|
| | Max | @146 nt | T90 | T50 |
| Comparative | 100% | 100% | 100% | 100% |
| Example 1 | | | | |
| Example 1 | 107% | 116% | 343% | 157% |

Relative EQE Max: [a maximum external quantum efficiency of a given device/a maximum external quantum efficiency of a device of Comparative Example 1]×100%.

Relative EQE @146 nit: [an EQE @146 nit of a given device (i.e., the EQE of the given device at 146 nit)/an EQE @146 nit of the device of Comparative Example 1 (i.e., the EQE of the device of Comparative Example 1 at 146 nit)]×100%.

Relative T90: [T90 (hour) when a given device is driven at an initial luminance of 146 nit/T90 (hour) when the device of Comparative Example 1 is driven at an initial luminance of 146 nit]×100%.

Relative T50: [T50 (hour) when a given device is driven at an initial luminance of 146 nit/T50 (hour) when the device of Comparative Example 1 is driven at an initial luminance of 146 nit]×100%.

From the results of Table 2, it was confirmed that an electroluminescent device including the semiconductor nanoparticle of Preparation Example may exhibit improved electroluminescent properties compared to Comparative Example 1, and may exhibit a significantly extended lifetime.

In an embodiment, a method of treating a semiconductor nanoparticle comprises:
adding a metal halide to a first dispersion including a liquid medium and a semiconductor nanoparticle dispersed in the liquid medium, precipitating the semiconductor nanoparticle;
adding and mixing a ligand compound to and with the first dispersion including the precipitated semiconductor nanoparticle, obtaining a second dispersion in which a semiconductor nanoparticle surface-treated with the ligand compound is dispersed in the liquid medium; and
recovering the surface-treated semiconductor nanoparticle from the second dispersion.

In an embodiment, the metal halide may include zinc, aluminum, indium, gallium, or a combination thereof.

In an embodiment, the metal halide may include ZnCl₂, AlCl₃, InCl₃, GaCl₃, ZnI₂, or a combination thereof.

In an embodiment, the liquid medium may include one or more (for example, two or more) organic solvents. The organic solvent may have a boiling point at atmospheric pressure of greater than or equal to about 130° C., greater than or equal to about 150° C., or greater than or equal to about 180° C. and less than or equal to about 400° C. The boiling point may be greater than or equal to about 200° C. and less than or equal to about 380° C.

In an embodiment, the liquid medium may include a substituted or unsubstituted C6 to C40 aromatic hydrocarbon solvent; a substituted or unsubstituted C6 to C15 aliphatic hydrocarbon solvent; a substituted or unsubstituted C6 to C40 amine solvent; or a combination thereof.

In an embodiment, the liquid medium may include cyclohexylbenzene, trioctylamine, or a combination thereof.

In an embodiment, the ligand compound may include a carboxyl group, an amine group, or a combination thereof.

In an embodiment, the surface-treated semiconductor nanoparticle may include a first organic ligand. The first organic ligand may be derived from the ligand compound. The semiconductor nanoparticle before surface treatment (for example, in the first dispersion) may include a second organic ligand different from the first organic ligand. The first organic ligand may include a carboxylate moiety, an amine moiety, or a combination thereof. The second organic ligand may include a carboxylate moiety, an amine moiety, or a combination thereof.

In an embodiment, the first organic ligand may have a carbon number of greater than or equal to about 2, or greater than or equal to about 5 and less than or equal to about 16, less than or equal to about 14, or less than or equal to about 10. The second organic ligand may have a carbon number of greater than or equal to about 14, or greater than or equal to about 17 and less than or equal to about 40, or less than or equal to about 24. The second organic ligand may have a molecular weight greater than that of the first organic ligand.

In an embodiment, the first organic ligand may include a hexanoate moiety substituted with a C1-C4 alkyl group, a butanoate moiety substituted with a C1-C4 alkyl group, a pentanoate moiety substituted with a C1-C4 alkyl group, an octanoate moiety substituted with a C1-C4 alkyl group, or a combination thereof. The first organic ligand may include a hexanoate group, a methylbutanoate group, a butyloctanoate group, or a combination thereof.

In an embodiment, the second organic ligand may include a linear or branched aliphatic hydrocarbon group (for example, an alkyl group, an alkenyl group, or an alkynyl group) of C13-C25, C14-C23, C15-C22, C16-C21, C17-C20, or C18-C19. The second organic ligand may include an aliphatic hydrocarbon group having a carbon number of greater than or equal to about 17.

In an embodiment, the second organic ligand may include, for example, one or more, or two or more carbon-carbon double bonds in the aliphatic hydrocarbon group chain. The first organic ligand may include a branched alkyl group, and the second organic ligand may include a linear alkenyl group. The first organic ligand may be bound to or disposed on a surface of the semiconductor nanocrystal. The second organic ligand may be bound to or disposed on the surface of the semiconductor nanocrystal.

In an embodiment, a total sum of carbon numbers of the first organic ligand and the second organic ligand may be greater than or equal to about 20, greater than or equal to about 22, greater than or equal to about 24, greater than or equal to about 28, or greater than or equal to about 29. The total sum of carbon numbers may be less than or equal to about 34, less than or equal to about 32, less than or equal to about 30, less than or equal to about 28, or less than or equal to about 27.

In an embodiment, the first organic ligand may have a molecular weight of greater than or equal to about 90 g/mol, or greater than or equal to about 100 g/mol and less than or equal to about 260 g/mol, less than or equal to about 230 g/mol, less than or equal to about 210 g/mol, less than or equal to about 205 g/mol, less than or equal to about 200 g/mol, or less than or equal to about 170 g/mol.

In an embodiment, the second organic ligand may have a molecular weight of greater than about 200 g/mol, greater than or equal to about 225 g/mol, greater than or equal to about 250 g/mol, or greater than or equal to about 280 g/mol, and less than or equal to about 500 g/mol, or less than or equal to about 250 g/mol.

In an embodiment, the first organic ligand may include a substituted or unsubstituted C6 to C12 aromatic hydrocarbon group; a substituted or unsubstituted linear or branched aliphatic hydrocarbon group of C3 to C12, or C5 to C9, or C4 to C8, or C6 to C7 (for example, an alkyl group, an alkenyl group, or an alkynyl group); or a combination thereof.

In an embodiment of the method, the mixing may be performed at a temperature of greater than or equal to about 120° C., or greater than or equal to about 160° C. The mixing may be performed at a temperature of less than or equal to about 250° C., or less than or equal to about 240° C.

In an embodiment, the metal halide may be added to the first dispersion in a form of a solution in a solvent miscible with the liquid medium. The solvent may include a C3-C10 ketone solvent such as acetone, a C1-C10 alcohol solvent such as ethanol, a C1-C40 or C3-C30 alkylphosphine solvent such as trioctylphosphine, or a combination thereof.

In an embodiment, the metal halide may be added in an amount such that a concentration in the liquid medium is greater than or equal to about 0.00001 M, greater than or equal to about 0.00005 M, greater than or equal to about 0.0001 M, greater than or equal to about 0.0005 M, greater than or equal to about 0.001 M, greater than or equal to about 0.005 M, or in a range of greater than or equal to about 0.01 M to less than or equal to about 100 M. An amount of the ligand compound may be less than or equal to about 5000 mole %, or in a range of greater than or equal to about 0.01 mole % to less than or equal to about 1000 mole %, based on the metal halide.

In an embodiment, addition of the metal halide may precipitate greater than or equal to about 80%, or greater than or equal to about 90%, of the semiconductor nanoparticles in the first dispersion. Addition of the metal halide may precipitate greater than or equal to about 95%, or greater than or equal to about 99%, of the semiconductor nanoparticles in the first dispersion. The recovery may include adding a precipitation solvent to the second dispersion. The precipitation solvent may include acetone, ethanol, butanol, isopropanol, ethanediol, water, tetrahydrofuran (THF), dimethyl sulfoxide (DMSO), diethyl ether, formaldehyde, acetaldehyde, ethylene glycol, or a solvent having a solubility parameter similar to those of the listed solvents.

An embodiment relates to an ink composition including a semiconductor nanoparticle (for example, treated by the treatment method described above) and a liquid vehicle. An embodiment relates to the semiconductor nanoparticle.

In an embodiment, the liquid vehicle may include an organic solvent having a boiling point of greater than or equal to about 150° C. and less than or equal to about 380° C., and the semiconductor nanoparticle may include a first organic ligand having a carbon number of greater than or equal to about 2 and less than or equal to about 16.

In an embodiment of the ink composition, the semiconductor nanoparticle may have a DLS particle diameter of greater than or equal to about 1 nm and less than about 400 nm, or greater than or equal to about 5 nm and less than or equal to about 100 nm.

In an embodiment, the liquid vehicle may include a substituted or unsubstituted C6 to C40 aromatic hydrocarbon solvent; a substituted or unsubstituted C6 to C15 aliphatic hydrocarbon solvent; a substituted or unsubstituted C6 to C40 amine solvent; or a combination thereof. The liquid vehicle may include cyclohexylbenzene, trioctylamine, or a combination thereof.

In an embodiment, the semiconductor nanoparticle may include a first semiconductor nanocrystal; and a semiconductor nanocrystal shell disposed on the first semiconductor nanocrystal.

In an embodiment, the semiconductor nanoparticle may include a plurality of organic ligands (or a ligand system including the same), and the plurality of organic ligands may include a first organic ligand; and a second organic ligand different from the first organic ligand. The semiconductor nanoparticle may exhibit, in a gas chromatography (GC) analysis, a first peak assigned to the first organic ligand and a second peak assigned to the second organic ligand.

n an embodiment, the semiconductor nanoparticle may have a second organic ligand fraction calculated by the following equation that is less than or equal to about 80%, less than or equal to about 79%, or less than or equal to about 75%:

$$second organic ligand fraction = [ \text{} second peak area correction value / ( second peak area correction value + first peak area correction value ) ] \times 100 ( \% ) .$$

The second peak area correction value is a value obtained by dividing an area of the second peak by a molecular weight of the second organic ligand, and the first peak area correction value is a value obtained by dividing an area of the first peak by a molecular weight of the first organic ligand.

In an embodiment, the semiconductor nanoparticle may include zinc, sulfur, and selenium and may not include cadmium. The first organic ligand and the second organic ligand may each have a carboxylate moiety. The first organic ligand may include a branched alkyl group of C3 to C12 or C4 to C8. The second organic ligand may include an alkenyl group of C13 to C30 or C16 to C24.

Details regarding the first organic ligand and the second organic ligand are as described herein.

In an embodiment, in thermogravimetric analysis, a weight decreased (for example, an organic content) in a range of greater than or equal to about 200° C. to less than or equal to about 550° C. may be less than or equal to about 13%, less than or equal to about 11.5%, less than or equal to about 11%, less than or equal to about 8%, less than or equal to about 7.5 weight %, less than or equal to about 7.3 weight %, or less than or equal to about 6 weight %, based on a total weight of the semiconductor nanoparticle. The semiconductor nanoparticle, in thermogravimetric analysis, may have a weight decreased in the range of greater than or equal to about 200° C. to less than or equal to about 550° C. of greater than or equal to about 1 weight %, or greater than or equal to about 3%, based on the total weight of the semiconductor nanoparticle.

In an embodiment, in thermogravimetric analysis, a residue content at greater than or equal to about 550° C. may be greater than or equal to about 82%, greater than or equal to about 87%, greater than or equal to about 88%, or greater than or equal to about 89% and less than or equal to about 99%, less than or equal to about 93%, or less than or equal to about 91%, based on the total weight of the semiconductor nanoparticle.

In an embodiment, a ratio of a retention time (minutes) of the first peak to a retention time (minutes) of the second peak may be greater than or equal to about 0.1, greater than or equal to about 0.5, or greater than or equal to about 0.7 and less than or equal to about 1, or less than or equal to about 0.9. The retention time of the second peak may be longer than the retention time of the first peak. A difference in retention time between the second peak and the first peak may be greater than or equal to about 2 minutes, or greater than or equal to about 5 minutes. The difference in retention time between the second peak and the first peak may be less than or equal to about 12 minutes, or less than or equal to about 10 minutes.

In an embodiment, the semiconductor nanoparticle may further include a halogen (for example, chlorine).

In an embodiment, in the semiconductor nanoparticle, a mole ratio of halogen (for example, chlorine) to zinc may be greater than or equal to about 0.01:1, greater than or equal to about 0.05:1, greater than or equal to about 0.1:1, greater than or equal to about 0.15:1, or greater than or equal to about 0.2:1. In the semiconductor nanoparticle, the mole ratio of halogen (for example, chlorine) to zinc may be less than or equal to about 1:1, less than or equal to about 0.9:1, less than or equal to about 0.7:1, or less than or equal to about 0.5:1.

In an embodiment, the semiconductor nanoparticle, the first semiconductor nanocrystal, or the semiconductor nanocrystal shell may include a Group II-VI compound, a Group III-V compound, a Group IV-VI compound, a Group IV element or compound, a Group II-III-VI compound, a Group I-III-VI compound, a Group I-II-IV-VI compound, or a combination thereof.

In an embodiment, the semiconductor nanoparticle or the first semiconductor nanocrystal may include an indium phosphide, an indium zinc phosphide, a zinc selenide, a zinc telluride, a zinc tellurium selenide, a silver indium gallium sulfide, a silver indium sulfide, or a combination thereof.

In an embodiment, the semiconductor nanoparticle or the semiconductor nanocrystal shell may include a zinc selenide, a zinc selenide telluride, a zinc selenide sulfide, a zinc sulfide, or a combination thereof.

In an embodiment, the semiconductor nanocrystal shell may include a first shell layer; and a second shell layer disposed on the first shell layer. The first shell layer may include a zinc selenide, a zinc selenide telluride, a zinc selenide sulfide, or a combination thereof. The second shell layer may include a zinc selenide sulfide, a zinc sulfide, or a combination thereof.

In an embodiment, the semiconductor nanoparticle may not include lead. The semiconductor nanoparticle may not include copper.

In an embodiment, the semiconductor nanoparticle may be configured to emit a first light.

In an embodiment, the first light may exhibit a red light spectrum, a green light spectrum, or a blue light spectrum. A full width at half maximum of a peak emission wavelength of the first light may be greater than or equal to about 1 nm and less than or equal to about 55 nm.

In an embodiment, the first light may be blue light. A peak emission wavelength of the first light or the blue light may be greater than or equal to about 440 nm and less than or equal to about 480 nm.

In an embodiment, the first light may be green light. A peak emission wavelength of the first light or the green light may be greater than or equal to about 500 nm and less than or equal to about 580 nm.

In an embodiment, the first light may be red light. A peak emission wavelength of the first light or the red light may be greater than or equal to about 600 nm and less than or equal to about 680 nm.

In an embodiment, the semiconductor nanoparticle may not substantially exhibit a peak assigned to a thiol in a gas chromatogram. In the gas chromatogram, an area ratio of a peak assigned to a thiol with respect to the second peak may be less than or equal to about 10%, less than or equal to about 5%, less than or equal to about 2%, or less than or equal to about 1%.

In an embodiment, the semiconductor nanoparticle may have a particle size or an average particle size (hereinafter, “particle size”) of greater than or equal to about 3 nm, greater than or equal to about 5 nm, greater than or equal to about 8 nm, greater than or equal to about 10 nm, or greater than or equal to about 12 nm and less than or equal to about 50 nm, or less than or equal to about 45 nm.

In an embodiment, the semiconductor nanoparticle, in dynamic light scattering analysis, may exhibit a DLS particle diameter of less than about 300 nm. The DLS particle diameter may be less than or equal to about 200 nm, less than or equal to about 100 nm, or less than or equal to about 50 nm. The DLS particle diameter may be greater than or equal to about 10 nm, or greater than or equal to about 15 nm.

In an embodiment, an electroluminescent device comprises a first electrode and a second electrode that are spaced apart from each other, and an emission layer disposed between the first electrode and the second electrode, wherein the emission layer comprises the semiconductor nanoparticle described above.

In an embodiment, the emission layer may be configured to emit a first light upon application of a voltage.

In an embodiment, a peak emission wavelength of the first light or of the semiconductor nanoparticle (electroluminescent or photoluminescent) may be greater than or equal to about 440 nm, or greater than or equal to about 460 nm and less than or equal to about 480 nm, or less than or equal to about 470 nm.

In an embodiment, a peak emission wavelength of the first light or of the semiconductor nanoparticle may be greater than or equal to about 500 nm, or greater than or equal to about 510 nm and less than or equal to about 580 nm, or less than or equal to about 540 nm. In an embodiment, a peak emission wavelength of the first light or of the semiconductor nanoparticle may be greater than or equal to about 600 nm, or greater than or equal to about 610 nm and less than or equal to about 680 nm, or less than or equal to about 635 nm.

In an embodiment, the first electrode may be an anode and the second electrode may be a cathode.

In an embodiment, the electroluminescent device may further include a charge auxiliary layer between the emission layer and the first electrode, between the emission layer and the second electrode, or between both.

In an embodiment, the electroluminescent device may further include a hole auxiliary layer between the emission layer and the first electrode. The electroluminescent device may further include an electron auxiliary layer between the emission layer and the second electrode.

In an embodiment, the charge auxiliary layer may include a hole auxiliary layer including an organic compound, an electron auxiliary layer including metal oxide nanoparticles, or a combination thereof.

In an embodiment, the electroluminescent device may have a maximum luminance of greater than or equal to about 10,000 cd/m², greater than or equal to about 80,000 cd/m², greater than or equal to about 90,000 cd/m², or greater than or equal to about 100,000 cd/m².

In an embodiment, the electroluminescent device may have a maximum external quantum efficiency of greater than or equal to about 3%, greater than or equal to about 5%, greater than or equal to about 9%, greater than or equal to about 10%, or greater than or equal to about 11%.

In an embodiment, the electroluminescent device may have a T90 of greater than or equal to about 10 hours, or greater than or equal to about 30 hours, when measured at an initial luminance of 146 nit.

An embodiment relates to an electronic device or a display device including the electroluminescent device.

The display device or the electronic device may include a virtual reality display device, an augmented reality display device, a portable terminal device, a monitor, a laptop computer, a television, an electronic signboard, a camera, or an automotive electronic component.

While this disclosure has been described in connection with what is presently considered to be practical embodiments, it is to be understood that the present subject matter is not limited to the disclosed exemplary embodiments. On the contrary, it is intended to cover various modifications and equivalent arrangements included within the spirit and scope of the appended claims.

What is claimed is:

1. A method of treating a semiconductor nanoparticle, the method comprising:
adding a metal halide to a first dispersion including a liquid medium and a semiconductor nanoparticle to precipitate the semiconductor nanoparticle to provide a precipitated semiconductor nanoparticle;
adding a ligand compound to the first dispersion and mixing the ligand compound with the first dispersion including the precipitated semiconductor nanoparticle to obtain a second dispersion in which a semiconductor nanoparticle surface treated with the ligand compound is dispersed in the liquid medium to provide a surface-treated semiconductor nanoparticle; and
recovering the surface-treated semiconductor nanoparticle from the second dispersion.

2. The method of claim 1,
wherein the metal halide comprises zinc, indium, aluminum, gallium, or a combination thereof.

3. The method of claim 1,
wherein the metal halide comprises ZnCl₂, AlCl₃, InCl₃, GaCl₃, ZnI₂, or a combination thereof.

4. The method of claim 1,
wherein the liquid medium comprises an organic solvent having a boiling point of greater than or equal to about 130° C., or greater than or equal to about 180° C. and less than or equal to about 400° C. at atmospheric pressure.

5. The method of claim 2,
wherein the liquid medium comprises a substituted or unsubstituted C6 to C40 aromatic hydrocarbon solvent; a substituted or unsubstituted C6 to C15 aliphatic hydrocarbon solvent; a substituted or unsubstituted C6 to C40 amine solvent; or a combination thereof.

6. The method of claim 1,
wherein the surface-treated semiconductor nanoparticle comprises a first organic ligand derived from the ligand compound, and the ligand compound comprises a compound represented by Chemical Formula 2: 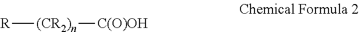
wherein, in Chemical Formula 2, each R is the same or different and each independently hydrogen or a C1 to C6 alkyl group, and n is 1 to 10.

7. The method of claim 6,
wherein the surface-treated semiconductor nanoparticle further comprises a second organic ligand different from the first organic ligand.

8. The method of claim 7,
wherein the second organic ligand comprises a C16 to C30 carboxylic acid compound including a carbon-carbon double bond in a carbon chain.

9. The method of claim 7,
wherein the surface-treated semiconductor nanoparticle exhibits, as confirmed by a gas chromatography analysis, a first peak assigned to the first organic ligand and a second peak assigned to the second organic ligand,
and a fraction of the second organic ligand defined by the following equation is less than or equal to about 60%:
Second organic ligand fraction=[second peak area correction value/(first peak area correction value+second peak area correction value)]×100(%)
wherein the second peak area correction value is a value obtained by dividing an area of the second peak by a molecular weight of the second organic ligand, and the first peak area correction value is a value obtained by dividing an area of the first peak by a molecular weight of the first organic ligand.

10. The method of claim 9,
wherein the fraction of the second organic ligand is greater than or equal to about 1% and less than or equal to about 35%.

11. The method of claim 5,
wherein the surface-treated semiconductor nanoparticle has, in thermogravimetric analysis, a weight decrease in a range of greater than or equal to about 200° C. to less than or equal to about 550° C. that is greater than or equal to about 1% and less than or equal to about 10%, based on a total weight of the surface-treated semiconductor nanoparticle.

12. The method of claim 1,
wherein the mixing is performed at a temperature of greater than or equal to about 120° C. and less than or equal to about 250° C.

13. A semiconductor nanoparticle, comprising:
a first semiconductor nanocrystal; and a semiconductor nanocrystal shell disposed on the first semiconductor nanocrystal,
wherein the semiconductor nanoparticle further comprises a plurality of organic ligands,
the plurality of organic ligands comprises a first organic ligand; and optionally a second organic ligand different from the first organic ligand,
the first organic ligand comprises a branched alkyl group of C3 to C12, and the second organic ligand comprises an alkenyl group of C13 to C30,
the semiconductor nanoparticle exhibits, in gas chromatography analysis, a first peak assigned to the first organic ligand and optionally a second peak assigned to the second organic ligand,
and a fraction of the second organic ligand defined by the following equation is greater than or equal to about 0% and less than or equal to about 60%:
$$Second organic ligand fraction = [ \text{} second peak area correction value / ( first peak area correction value + second peak area correction value ) ] \times 100 ( \% )$$
wherein the second peak area correction value is a value obtained by dividing an area of the second peak by a molecular weight of the second organic ligand, and the first peak area correction value is a value obtained by dividing an area of the first peak by a molecular weight of the first organic ligand.

14. The semiconductor nanoparticle of claim 13,
wherein the first organic ligand comprises a moiety represented by Chemical Formula 1-1: 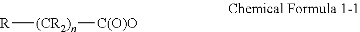
wherein, in Chemical Formula 1-1, each R is the same or different and each independently hydrogen or a C1 to C6 alkyl group, and n is an integer of 1 to 10;
and the second organic ligand comprises a C16 to C30 carboxylic acid compound including a carbon-carbon double bond in a carbon chain.

15. The semiconductor nanoparticle of claim 13, wherein the fraction of the second organic ligand is greater than or equal to about 0.01% and less than or equal to about 40%.

16. The semiconductor nanoparticle of claim 13, wherein the semiconductor nanoparticle has, in thermogravimetric analysis, a weight decrease in a range of greater than or equal to about 200° C. to less than or equal to about 550° C. that is greater than or equal to about 1% and less than or equal to about 10%, based on a total weight of the semiconductor nanoparticle.

17. The semiconductor nanoparticle of claim 13, wherein the semiconductor nanoparticle has, in thermogravimetric analysis, a weight decrease in a range of greater than or equal to about 200° C. to less than or equal to about 550° C. that is less than or equal to about 7.5%, based on a total weight of the semiconductor nanoparticle.

18. An electroluminescent device comprising:
a first electrode and a second electrode that are spaced apart from each other; and
an emission layer disposed between the first electrode and the second electrode,
wherein the emission layer comprises the semiconductor nanoparticle of claim 13.

19. An ink composition comprising:
a liquid vehicle; and a semiconductor nanoparticle,
wherein the liquid vehicle comprises an organic solvent having a boiling point of greater than or equal to about 150° C. and less than or equal to about 380° C.,
the semiconductor nanoparticle further comprises a plurality of organic ligands,
wherein the plurality of organic ligands includes a first organic ligand and optionally a second organic ligand different from the first organic ligand,
the first organic ligand comprises a branched alkyl group of C3 to C12, and the second organic ligand comprises an alkenyl group of C13 to C30,
the semiconductor nanoparticle exhibits a first peak assigned to the first organic ligand and optionally a second peak assigned to the second organic ligand, in a gas chromatography analysis,
and a fraction of the second organic ligand as defined by the following equation is less than or equal to about 60%:
second organic ligand fraction=[second peak area correction value/(first peak area correction value+second peak area correction value)]×100(%)
wherein the second peak area correction value is a value obtained by dividing an area of the second peak by a molecular weight of the second organic ligand, and the first peak area correction value is a value obtained by dividing an area of the first peak by a molecular weight of the first organic ligand.

20. The ink composition of claim 19,
wherein the first organic ligand comprises a moiety represented by Chemical Formula 1-1: 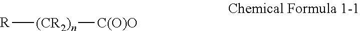
wherein, in Chemical Formula 1-1, each R is the same or different and each independently hydrogen or a C1 to C6 alkyl group, and n is an integer of 1 to 10;
and the second organic ligand comprises a C16 to C30 carboxylic acid compound including a carbon-carbon double bond in a carbon chain, or
the fraction of the second organic ligand is greater than or equal to about 3% and less than or equal to about 40%.
